(19) United States
(12) Patent Application Publication
(10) Pub. No.: US 2024/0258357 A1
(43) Pub. Date: Aug. 1, 2024

(54) SEMICONDUCTOR DEVICE, METHOD OF MANUFACTURING SEMICONDUCTOR DEVICE, AND ELECTRONIC EQUIPMENT

(71) Applicant: SONY SEMICONDUCTOR SOLUTIONS CORPORATION, Kanagawa (JP)

(72) Inventors: Kodai KANEYASU, Kanagawa (JP); Takeo ONISHI, Kanagawa (JP)

(73) Assignee: SONY SEMICONDUCTOR SOLUTIONS CORPORATION, Kanagawa (JP)

(21) Appl. No.: 18/566,939

(22) PCT Filed: May 24, 2022
(86) PCT No.: PCT/JP2022/021180

§ 371 Date: Dec. 4, 2023

(30) Foreign Application Priority Data
Jun. 11, 2021 (JP) 2021-097809

(51) Int. Cl. H01L 27/146

(52) U.S. Cl. CPC H01L 27/14638; H01L 27/14607; H01L 27/14614; H01L 27/14643; H01L 27/14689

(57) ABSTRACT

A semiconductor device, a method of manufacturing the semiconductor device, and electronic equipment that make it possible to easily transfer a charge at a deep position in a substrate. A semiconductor device includes a photo-electric converting section, and a transfer transistor that transfers the charge of the photo-electric converting section to a charge accumulation section. The transfer transistor has a vertical gate electrode including an embedded electrode part embedded in a semiconductor substrate. The embedded electrode part includes an embedded upper electrode and an embedded lower electrode on a substrate deep-portion side relative to the embedded upper electrode and that has an electrode area size, in a plan view, greater than an electrode area size of the embedded upper electrode. The present disclosure can be applied to, for example, a solid-state imaging element including, in each pixel, a transfer transistor that transfers a charge accumulated in a photodiode section.

### TECHNICAL FIELD

The present disclosure relates to a semiconductor device, a method of manufacturing the semiconductor device, and electronic equipment, and in particular relates to a semiconductor device, a method of manufacturing the semiconductor device, and electronic equipment that make it possible to easily transfer a charge at a deep position in a substrate.

### BACKGROUND ART

There is a technology that makes it possible to read out a charge from a photodiode section formed at a deep position in a semiconductor substrate, when the charge is to be transferred from the photodiode section to an FD (Floating Diffusion) section in a CMOS image sensor, by giving a potential gradient in the vertical direction with the use of a vertical gate electrode. However, since the vertical gate electrode itself has the same potential, if the length of the vertical gate electrode (the length in the substrate depth direction) is extended, it becomes difficult to generate a potential gradient in the depth direction, and it becomes hard to read out the charge.

In view of this, for example, PTL 1 proposes a technology of giving a potential gradient in the vertical direction by forming a plurality of vertical gate electrodes having different diameters in the depth direction of a semiconductor substrate, to thereby efficiently transfer a charge of a photodiode section to an FD section.

In addition, for example, PTL 2 proposes a technology of giving a potential gradient in the vertical direction by forming a gate insulating film such that its film thickness gradually decreases toward the transfer destination of a charge, to thereby efficiently transfer a charge of a photodiode section to an FD section.

### CITATION LIST

### Patent Literature

PTL 1: JP 2016-162788A
PTL 2: JP 2018-148039A

### SUMMARY

### Technical Problem

According to the technologies proposed in PTL 1 and PTL 2, it is possible to give a potential gradient in the substrate depth direction. At this time, in terms of the transfer of a charge at a deeper position in a substrate, it is desirable if modulation at an electrode distal end is intense. However, it is not possible with conventional vertical gate electrode structures to locally increase modulation at the distal end. Accordingly, the deeper the position from which a charge is transferred is, the harder it is to transfer the charge.

The present disclosure has been made in view of such a situation, and makes it possible to easily transfer a charge at a deep position in a substrate.

### Solution to Problem

A semiconductor device according to a first aspect of the present disclosure includes a photo-electric converting section that generates a charge according to a received light amount, and a transfer transistor that transfers the charge of the photo-electric converting section to a predetermined charge accumulation section. The transfer transistor has a vertical gate electrode including an embedded electrode part embedded in a semiconductor substrate. The embedded electrode part includes an embedded upper electrode and an embedded lower electrode that is arranged on a substrate deep-portion side relative to the embedded upper electrode and that is formed to have an electrode area size, in a plan view, greater than an electrode area size of the embedded upper electrode.

A method of manufacturing a semiconductor device according to a second aspect of the present disclosure includes forming an embedded electrode part embedded in a semiconductor substrate, as a vertical gate electrode of a transfer transistor that transfers a charge generated according to a received light amount by a photo-electric converting section to a predetermined charge accumulation section. The embedded electrode part includes an embedded upper electrode and an embedded lower electrode that is arranged on a substrate deep-portion side relative to the embedded upper electrode and that is formed to have an electrode area size, in a plan view, greater than an electrode area size of the embedded upper electrode.

Electronic equipment according to a third aspect of the present disclosure includes a semiconductor device including a photo-electric converting section that generates a charge according to a received light amount, and a transfer transistor that transfers the charge of the photo-electric converting section to a predetermined charge accumulation section. The transfer transistor has a vertical gate electrode including an embedded electrode part embedded in a semiconductor substrate. The embedded electrode part includes an embedded upper electrode and an embedded lower electrode that is arranged on a substrate deep-portion side relative to the embedded upper electrode and that is formed to have an electrode area size, in a plan view, greater than an electrode area size of the embedded upper electrode.

In the first to third aspects of the present disclosure, the embedded electrode part embedded in the semiconductor substrate is provided as the vertical gate electrode of the transfer transistor that transfers a charge of the photo-electric converting section that generates the charge according to the received light amount, to the predetermined charge accumulation section, and the embedded electrode part includes the embedded upper electrode and the embedded lower electrode that is arranged on the substrate deep-portion side relative to the embedded upper electrode and that is formed to have the electrode area size, in a plan view, greater than the electrode area size of the embedded upper electrode.

The semiconductor device and the electronic equipment may be discrete devices, or may be modules to be incorporated into other devices.

### BRIEF DESCRIPTION OF DRAWINGS

FIG. 1 depicts views of the basic structure of a vertical gate electrode according to a first embodiment of the present disclosure.

FIG. 2 depicts views of the structure of a vertical gate electrode as a comparative example to be explained by comparison with the vertical gate electrode of FIG. 1.

FIG. 3 depicts views of the potential of each of the vertical gate electrodes of FIG. 1 and FIG. 2.

FIG. 4 depicts views of a more specific first configuration example of the vertical gate electrode of FIG. 1.

FIG. 5 depicts views of a more specific second configuration example of the vertical gate electrode of FIG. 1.

FIG. 6 depicts views of a more specific third configuration example of the vertical gate electrode of FIG. 1.

FIG. 7 depicts views of a more specific fourth configuration example of the vertical gate electrode of FIG. 1.

FIG. 8 depicts views for explaining a method of manufacturing the vertical gate electrode of FIG. 1.

FIG. 9 depicts views of a first layout example of the vertical gate electrode of FIG. 1.

FIG. 10 depicts views of a second layout example of the vertical gate electrode of FIG. 1.

FIG. 11 depicts views of a third layout example of the vertical gate electrode of FIG. 1.

FIG. 12 depicts views of a fourth layout example of the vertical gate electrode of FIG. 1.

FIG. 13 depicts views of the basic structure of a vertical gate electrode according to a second embodiment of the present disclosure.

FIG. 14 depicts views of a more specific first configuration example of the vertical gate electrode of FIG. 13.

FIG. 15 is a view for explaining a suitable impurity concentration of an impurity region around an embedded electrode part.

FIG. 16 depicts views of a simulation result of an electrical field formed by the vertical gate electrode according to the first embodiment.

FIG. 17 depicts views of a simulation result of an electrical field formed by the vertical gate electrode according to the second embodiment.

FIG. 18 depicts views for explaining a method of manufacturing the vertical gate electrode of FIG. 14.

FIG. 19 depicts views of a more specific second configuration example of the vertical gate electrode of FIG. 13.

FIG. 20 depicts views of a more specific third configuration example of the vertical gate electrode of FIG. 13.

FIG. 21 depicts views of a more specific fourth configuration example of the vertical gate electrode of FIG. 13.

FIG. 22 is a block diagram depicting the schematic configuration of a solid-state imaging element to which the technology according to the present disclosure is applied.

FIG. 23 is a block diagram depicting a configuration example of an imaging apparatus as electronic equipment to which the technology according to the present disclosure is applied.

FIG. 24 is a view depicting an example of a schematic configuration of an endoscopic surgery system.

FIG. 25 is a block diagram depicting an example of a functional configuration of a camera head and a camera control unit (CCU).

FIG. 26 is a block diagram depicting an example of schematic configuration of a vehicle control system.

FIG. 27 is a diagram of assistance in explaining an example of installation positions of an outside-vehicle information detecting section and an imaging section.

### DESCRIPTION OF EMBODIMENTS

Hereinbelow, modes for carrying out the technology according to the present disclosure (hereinafter, referred to as embodiments) will be explained with reference to the attached figures. The explanation will be given in the following order.
1. Basic Structure of Vertical Gate Electrode According to First Embodiment of Present Disclosure
2. First Configuration Example of Vertical Gate Electrode According to First Embodiment
3. Second Configuration Example of Vertical Gate Electrode According to First Embodiment
4. Third Configuration Example of Vertical Gate Electrode According to First Embodiment
5. Fourth Configuration Example of Vertical Gate Electrode According to First Embodiment
6. Method of Manufacturing Vertical Gate Electrode According to First Embodiment
7. Layout Examples of Vertical Transistor
8. Modification Examples of Vertical Gate Electrode
9. Basic Structure of Vertical Gate Electrode According to Second Embodiment of Present Disclosure
10. First Configuration Example of Vertical Gate Electrode According to Second Embodiment
11. Method of Manufacturing Vertical Gate Electrode According to Second Embodiment
12. Second Configuration Example of Vertical Gate Electrode According to Second Embodiment
13. Third Configuration Example of Vertical Gate Electrode According to Second Embodiment
14. Fourth Configuration Example of Vertical Gate Electrode According to Second Embodiment
15. Summary of Vertical Gate Electrode According to Second Embodiment
16. Example of Application to Solid-State Imaging Element
17. Example of Application to Electronic Equipment
18. Example of Application to Endoscopic Surgery System
19. Example of Application to Mobile Body

Note that identical or similar portions in the figures that are referred to in the following explanation are given identical or similar reference signs, and overlapping explanations are omitted as appropriate. The figures are schematic figures, and the relations between thicknesses and plane dimensions, the ratios of the thicknesses of respective layers, and the like are different from actual ones. In addition, different figures include portions that are depicted as having different mutual dimensional relations or ratios, in some cases.

In addition, definitions of directions such as the up-down direction in the following explanation are definitions that are used simply for convenience of explanation, and do not limit the technical idea of the present disclosure. For example, if a subject object is observed after being rotated 90°, the up-down direction mentioned in an explanation of the subject object is interpreted as meaning the left-right direction, and if the subject object is observed after being rotated 180°, the up-down direction mentioned in the explanation is interpreted as meaning an inverted direction.

### 1. Basic Structure of Vertical Gate Electrode According to First Embodiment of Present Disclosure

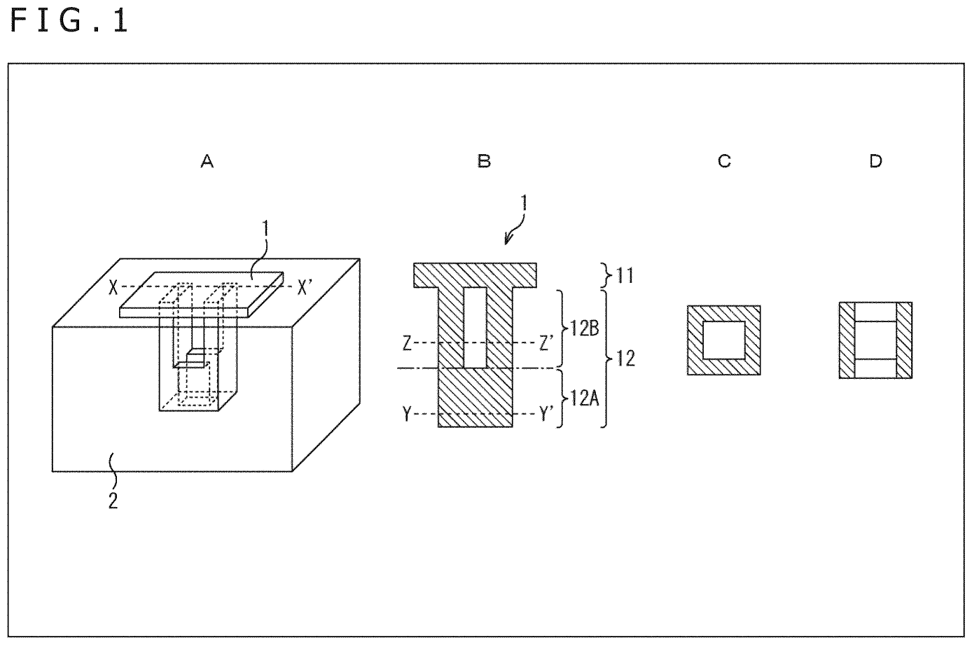

FIG. 1 depicts views of the basic structure of a vertical gate electrode according to a first embodiment of the present disclosure.

A of FIG. 1 is a perspective view depicting the overall structure of the vertical gate electrode according to the first embodiment of the present disclosure, and B of FIG. 1 is a cross-sectional view of the vertical gate electrode taken along a line X-X′ in A of FIG. 1. C of FIG. 1 is a plan view of the vertical gate electrode taken along a line Y-Y′ in B of FIG. 1, and D of FIG. 1 is a plan view of the vertical gate electrode taken along a line Z-Z′ in B of FIG. 1.

A vertical gate electrode 1 of FIG. 1 is a gate electrode of a vertical transistor included in a MOS transistor (MOS FET: Metal Oxide Semiconductor Field Effect Transistor) along with a drain electrode and a source electrode which are not depicted.

As depicted in A of FIG. 1, the vertical gate electrode 1 is formed in a Si substrate (silicon substrate) 2 which is a semiconductor substrate using silicon (Si) as a semiconductor. For example, the vertical transistor including the vertical gate electrode 1 reads out a charge of a photodiode section formed below the vertical gate electrode 1 in the Si substrate 2, and transfers the charge to a predetermined charge accumulation section.

As depicted in B of FIG. 1, the vertical gate electrode 1 has a planar electrode part 11 arranged at a position higher than a surface of the Si substrate 2 (hereinafter, also referred to as a substrate surface), and an embedded electrode part 12 embedded inside the Si substrate 2 (hereinafter, this is also described as “being in the substrate”). The vertical gate electrode 1 having the embedded electrode part 12 is configured to be able to easily read out a charge from a photodiode section formed at a deeper position in the substrate.

The embedded electrode part 12 includes two separate electrodes, i.e., an embedded lower electrode 12A on the substrate deep-portion side relative to a dashed line in B of FIG. 1 and an embedded upper electrode 12B on the substrate-surface side relative to the dashed line. The embedded lower electrode 12A is a rectangular tube with a hollow inside, as depicted in A to C of FIG. 1. As depicted in A to D of FIG. 1, the embedded upper electrode 12B includes two plate electrodes facing each other, and connects the planar electrode part 11 on a substrate top surface and the embedded lower electrode 12A at a substrate deep portion.

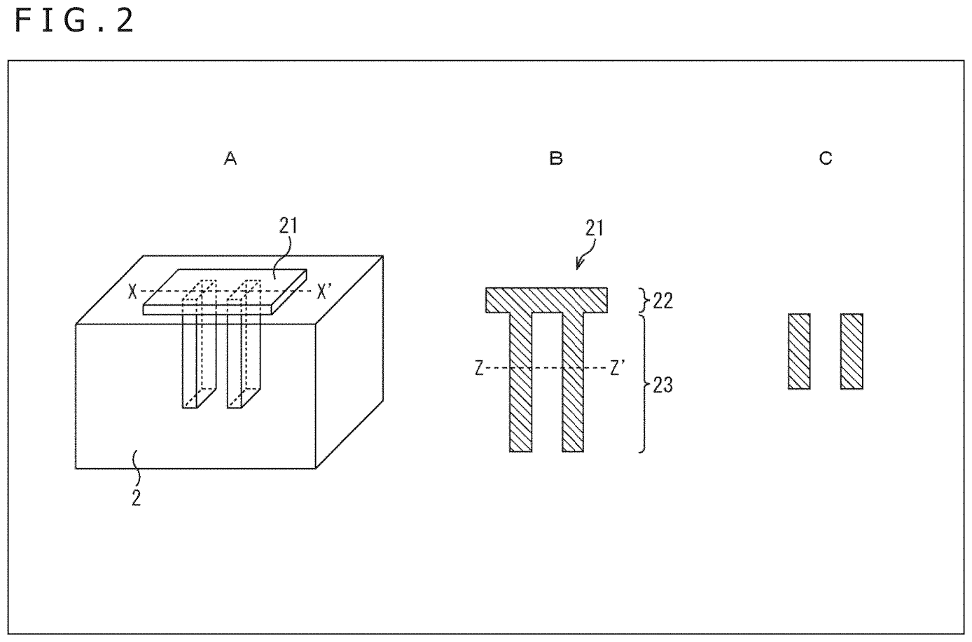

FIG. 2 depicts views of the structure of a vertical gate electrode as a comparative example for explaining advantages of the vertical gate electrode 1 of FIG. 1 by comparison.

A of FIG. 2 is a perspective view depicting the overall structure of the vertical gate electrode according to the comparative example, and B of FIG. 2 is a cross-sectional view of the vertical gate electrode taken along a line X-X′ in A of FIG. 2. C of FIG. 2 is a plan view of the vertical gate electrode taken along a line Z-Z′ in B of FIG. 2.

As depicted in B of FIG. 2, a vertical gate electrode 21 of FIG. 2 has a planar electrode part 22 arranged at a position higher than the substrate surface of the Si substrate 2, and an embedded electrode part 23 embedded in the substrate.

As depicted in A to C of FIG. 2, the embedded electrode part 23 includes two plate electrodes facing each other, and extends from the planar electrode part 11 toward the substrate deep-portion side. Whereas the embedded electrode part 23 of FIG. 2 has the two plate electrodes, which are facing each other, for comparison with the vertical gate electrode 1 of FIG. 1, the embedded electrode part 23 has one plate electrode in some cases.

As is apparent from the comparison with the vertical gate electrode 21 of FIG. 2, the vertical gate electrode 1 of FIG. 1 is different from the vertical gate electrode 21 of FIG. 2 in that it has the embedded lower electrode 12A formed as a rectangular tube. With the embedded lower electrode 12A, the vertical gate electrode 1 has a structure in which the tubular embedded lower electrode 12A surrounds a semiconductor layer of the Si substrate 2 at the distal end portion of the embedded electrode part 12. Accordingly, modulation is effected on the semiconductor layer from the four surfaces of the tubular embedded lower electrode 12A, and modulation at the distal end portion of the embedded electrode part 23 can be increased locally.

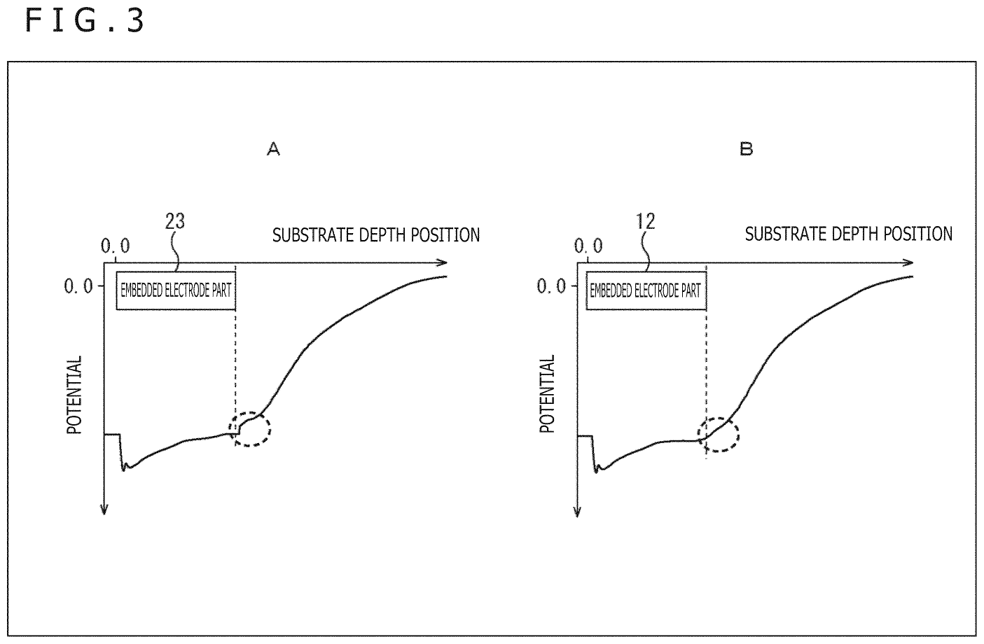

FIG. 3 depicts graphs depicting the potential, at substrate depth positions, of each of the vertical gate electrode 1 of FIG. 1 and the vertical gate electrode 21 of FIG. 2.

A of FIG. 3 is a graph depicting the potential of the vertical gate electrode 21 of FIG. 2 in relation to substrate depth positions of the Si substrate 2, and B of FIG. 3 is a graph depicting the potential of the vertical gate electrode 1 of FIG. 1 in relation to substrate depth positions of the Si substrate 2.

The horizontal axes of the graphs in A and B of FIG. 3 represent positions in the substrate depth directions (substrate depth positions) relative to substrate surfaces which are reference surfaces (0.0), and the vertical axes represent the potential. In addition, A and B of FIG. 3 depict, in the graphs, the depths of the embedded electrode parts 12 and 23 in simulations of the potential.

Attention is paid to portions that are surrounded by broken-line circles in A and B of FIG. 3, that is, changes of the potential near the bottoms of the embedded electrode parts 12 and 23. In the vertical gate electrode 21 of FIG. 2 as the comparative example, as depicted in A of FIG. 3, the potential lowers rapidly at positions below the bottom of the embedded electrode part 23. On the other hand, in the vertical gate electrode 1 of FIG. 1, as depicted in B of FIG. 3, the potential changes gently, and rapid lowering of the potential is suppressed even at positions below the bottom of the embedded electrode part 12. In other words, as compared with the vertical gate electrode 21 of FIG. 2, the electrical field formed near the bottom of the embedded electrode part 12 is intensified.

In such a manner, the vertical gate electrode 1 of FIG. 1, which has the embedded lower electrode 12A formed as a rectangular tube at the distal end portion of the gate electrode closest to the photodiode section formed at a deep position in the substrate, can increase the degree of modulation at the distal end portion. Hence, it is possible to facilitate the transfer of a charge from the photodiode section formed at a deep position in the substrate.

### 2. First Configuration Example of Vertical Gate Electrode According to First Embodiment

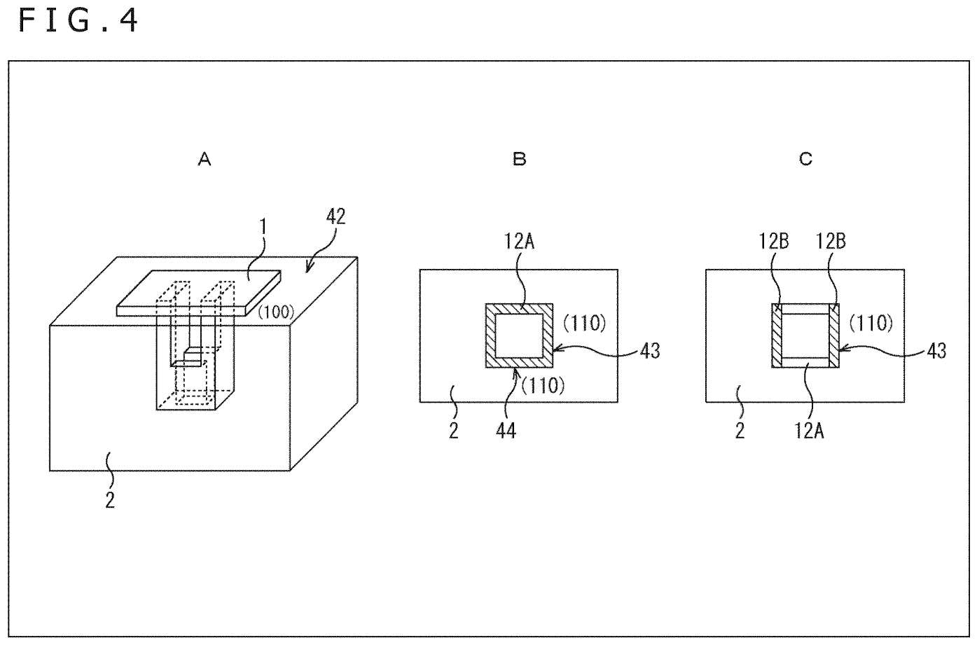

FIG. 4 depicts a more specific first configuration example of the vertical gate electrode 1 according to the first embodiment in FIG. 1.

A of FIG. 4 is a perspective view of the vertical gate electrode 1 in the first configuration example, B of FIG. 4 is a plan view of the vertical gate electrode 1 in the first configuration example taken along the line Y-Y′ in FIG. 1, and C of FIG. 4 is a plan view of the vertical gate electrode 1 in the first configuration example taken along the line Z-Z′ in FIG. 1.

The first configuration example is an example in which the vertical gate electrode 1 is formed in a Si (100) substrate used as the Si substrate 2. Accordingly, a substrate surface 42 of the Si substrate 2 includes a (100) orientation.

In addition, in the first configuration example in FIG. 4, as depicted in B and C of FIG. 4, the orientations of surfaces of the Si substrate 2 contacting a first surface 43 and a second surface 44 of the embedded electrode part 12 include (110) orientations. Here, the first surface 43 of the embedded electrode part 12 is equivalent to a longer-side side surface of the rectangle of the embedded upper electrode 12B in C of FIG. 4. On the other hand, the second surface 44 of the embedded electrode part 12 is equivalent to a shorter-side side surface orthogonal to the first surface 43.

### 3. Second Configuration Example of Vertical Gate Electrode According to First Embodiment

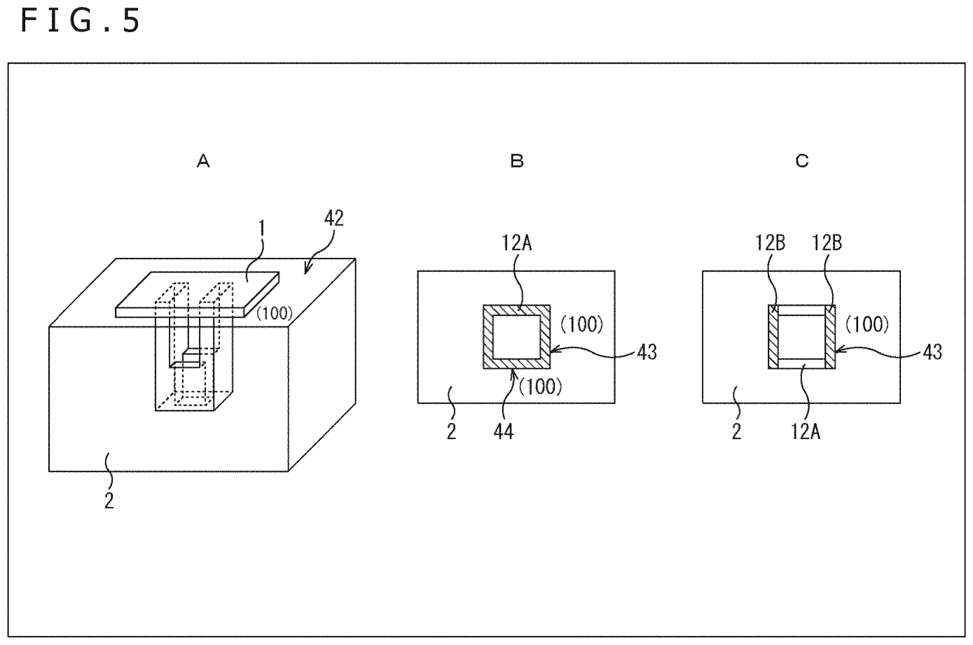

FIG. 5 depicts a more specific second configuration example of the vertical gate electrode 1 according to the first embodiment in FIG. 1.

A of FIG. 5 is a perspective view of the vertical gate electrode 1 in the second configuration example, B of FIG. 5 is a plan view of the vertical gate electrode 1 in the second configuration example taken along the line Y-Y′ in FIG. 1, and C of FIG. 5 is a plan view of the vertical gate electrode 1 in the second configuration example taken along the line Z-Z′ in FIG. 1.

The second configuration example is also an example in which the vertical gate electrode 1 is formed by using a Si (100) substrate as the Si substrate 2, similarly to the first configuration example. Accordingly, the substrate surface 42 of the Si substrate 2 includes a (100) orientation.

On the other hand, the second configuration example is different from the first configuration example in terms of the orientations of the surfaces of the Si substrate 2 contacting the first surface 43 and the second surface 44 of the embedded electrode part 12. Specifically, in the second configuration example, the orientations of the surfaces of the Si substrate 2 contacting the first surface 43 and the second surface 44 of the embedded lower electrode 12A and the embedded upper electrode 12B include (100) orientations. Since it is possible to reduce the interface state as compared with the first configuration example using the identical Si (100) substrate, the second configuration example is more preferable.

### 4. Third Configuration Example of Vertical Gate Electrode According to First Embodiment

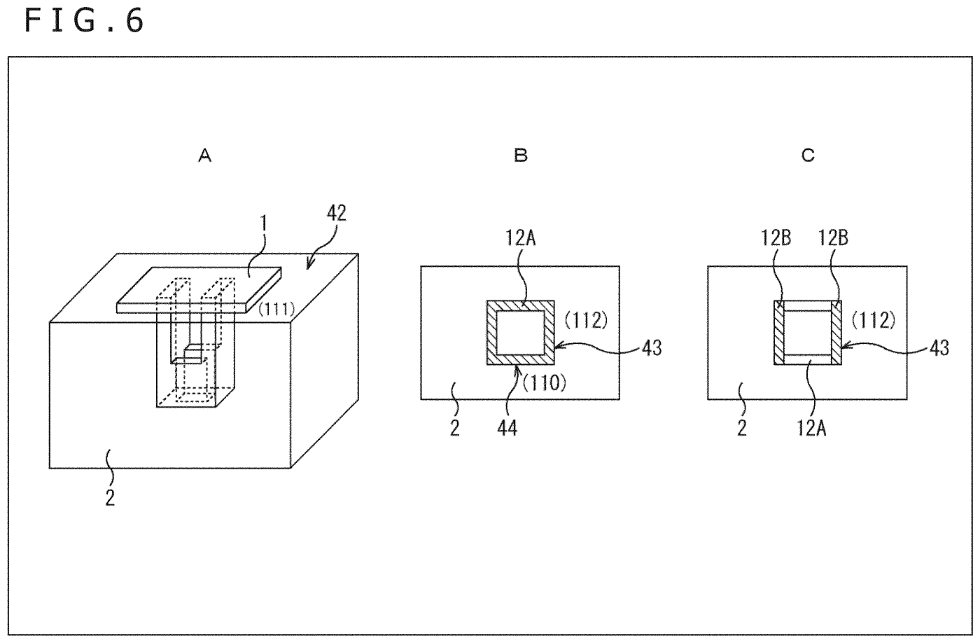

FIG. 6 depicts a more specific third configuration example of the vertical gate electrode 1 according to the first embodiment in FIG. 1.

A of FIG. 6 is a perspective view of the vertical gate electrode 1 in the third configuration example, B of FIG. 6 is a plan view of the vertical gate electrode 1 in the third configuration example taken along the line Y-Y′ in FIG. 1, and C of FIG. 6 is a plan view of the vertical gate electrode 1 in the third configuration example taken along the line Z-Z′ in FIG. 1.

The third configuration example is an example in which the vertical gate electrode 1 is formed in a Si (111) substrate used as the Si substrate 2. Accordingly, the substrate surface 42 of the Si substrate 2 includes a (111) orientation.

Further, in the third configuration example, the orientation of the surface of the Si substrate 2 contacting the first surface 43 of the embedded electrode part 12 includes a (112) orientation, and the orientation of the surface of the Si substrate 2 contacting the second surface 44 includes a (110) orientation.

### 5. Fourth Configuration Example of Vertical Gate Electrode According to First Embodiment

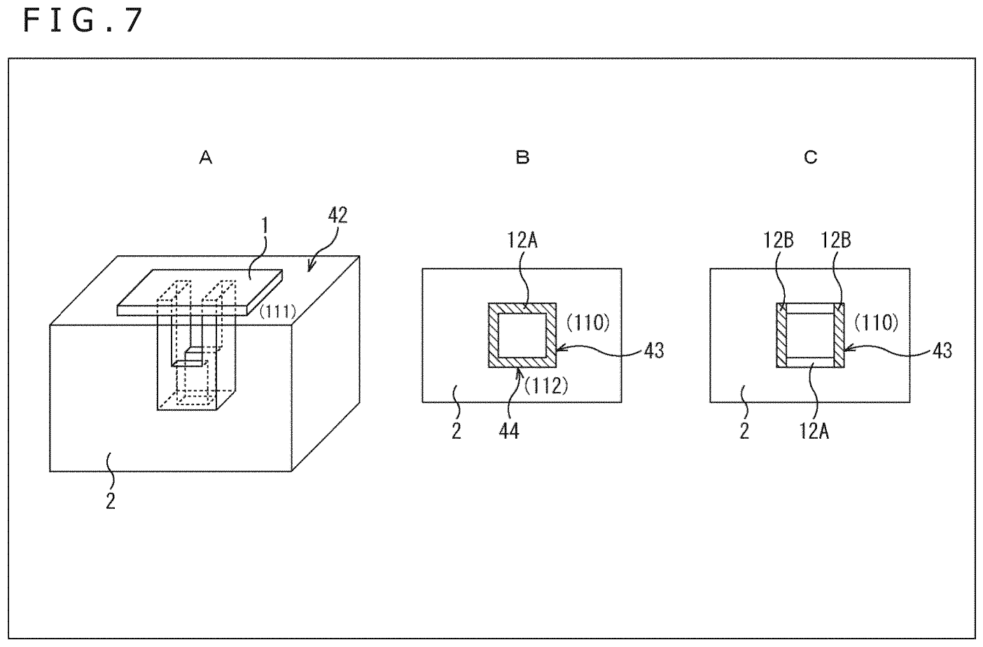

FIG. 7 depicts a more specific fourth configuration example of the vertical gate electrode 1 according to the first embodiment in FIG. 1.

A of FIG. 7 is a perspective view of the vertical gate electrode 1 in the fourth configuration example, B of FIG. 7 is a plan view of the vertical gate electrode 1 in the fourth configuration example taken along the line Y-Y′ in FIG. 1, and C of FIG. 7 is a plan view of the vertical gate electrode 1 in the fourth configuration example taken along the line Z-Z′ in FIG. 1. The fourth configuration example is also an example in which the vertical gate electrode 1 is formed by using a Si (111) substrate as the Si substrate 2, similarly to the third configuration example. Accordingly, the substrate surface 42 of the Si substrate 2 includes a (111) orientation.

On the other hand, in the fourth configuration example, the orientations of the surfaces of the Si substrate 2 contacting the first surface 43 and the second surface 44 of the embedded electrode part 12 are opposite to those in the third configuration example. That is, the orientation of the surface of the Si substrate 2 contacting the first surface 43 of the embedded electrode part 12 is a (110) orientation, and the orientation of the surface of the Si substrate 2 contacting the second surface 44 is a (112) orientation. Since it is possible to reduce the interface state as compared with the third configuration example using the identical Si (111) substrate, the fourth configuration example is more preferable.

### 6. Method of Manufacturing Vertical Gate Electrode According to First Embodiment

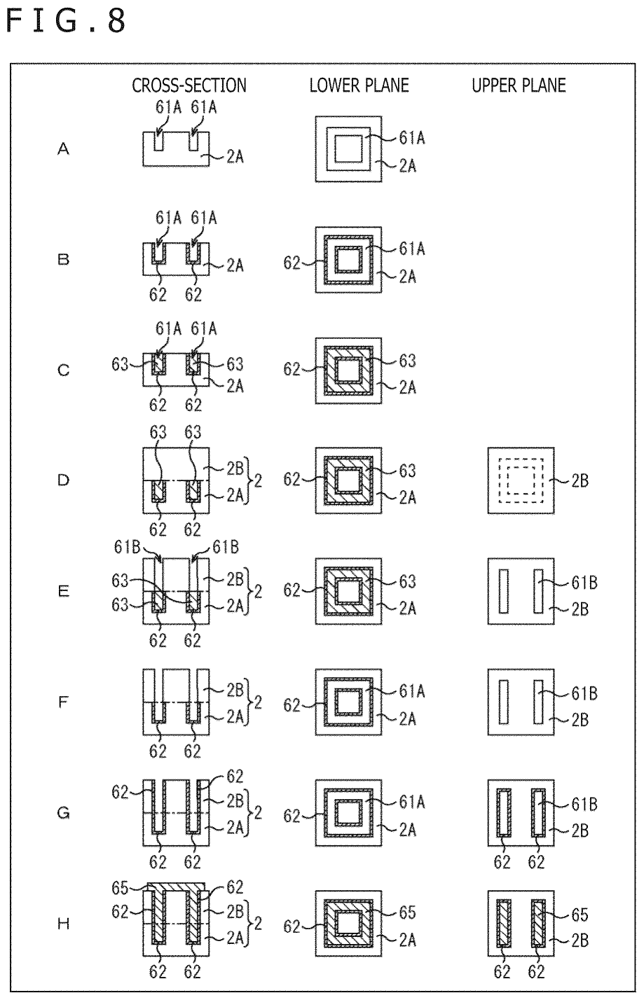

Next, a method of manufacturing the vertical gate electrode 1 according to the first embodiment is explained with reference to FIG. 8. In FIG. 8, cross-sectional views of the vertical gate electrode 1 at the time of formation are depicted on the left side, plan views equivalent to the portion of the embedded lower electrode 12A are depicted at the center, and plan views equivalent to the portion of the embedded upper electrode 12B are depicted on the right side.

First, as depicted in A of FIG. 8, an opening 61A is formed by etching, to a predetermined depth, a region of a Si substrate 2A where the embedded lower electrode 12A is to be formed. The planar shape of the opening 61A is a rectangular tube.

Next, as depicted in B of FIG. 8, a pinning region 62 where a charge transfer channel is to be formed is formed in a region to a predetermined depth (thickness) from a side wall and bottom surface of the opening 61A formed in the Si substrate 2A, by implanting P-type ions such as boron on the side wall and bottom surface of the opening 61A.

Next, as depicted in C of FIG. 8, a silicon oxide (SiO₂) 63 or the like is embedded in the opening 61A formed in the Si substrate 2A. Note that a material embedded in the opening 61 is not limited to the silicon oxide 63, and another material may be used.

Next, as depicted in D of FIG. 8, by epitaxial growth, a silicon layer 2B is additionally stacked on a top surface of the Si substrate 2A in which the silicon oxide 63 is embedded. The Si substrate 2 depicted in FIG. 1 corresponds to a stack of the Si substrate 2A and the silicon layer 2B. A dashed line depicted in the cross-sectional view in D of FIG. 8 is a boundary between the Si substrate 2A and the silicon layer 2B, and corresponds to the boundary between the embedded lower electrode 12A and the embedded upper electrode 12B represented by the dashed line in B of FIG. 1.

Next, as depicted in E of FIG. 8, openings 61B are formed by etching regions in the silicon layer 2B where the embedded upper electrode 12B is to be formed, until the silicon oxide 63 is exposed. The regions where the openings 61B are formed are regions equivalent to two opposite sides of the rectangular opening 61A formed in the Si substrate 2A.

Next, as depicted in F of FIG. 8, the silicon oxide 63 embedded in the opening 61A of the Si substrate 2A is removed by an HF process, for example. The opening 61A formed in the Si substrate 2A and the openings 61B formed in the silicon layer 2B are collectively referred to as openings 61.

Next, as depicted in G of FIG. 8, the pinning regions 62 are formed again in regions to predetermined depths (thicknesses) from side walls and bottom surfaces of the openings 61 by implanting P-type ions such as boron on the side walls and bottom surfaces of the openings 61.

Next, after gate insulating films (not depicted) are formed on the side walls and bottom surfaces of the openings 61 and the substrate top surface of the Si substrate 2, as depicted in H of FIG. 8, the vertical gate electrode 1 is completed by embedding an electrically conductive material 65 such as metal or polysilicon in the openings 61 and on the substrate top surface of the Si substrate 2.

In the cases of the first and second configuration examples of the vertical gate electrode 1 mentioned above, in the method of manufacturing the vertical gate electrode 1 mentioned above, the substrate surface of the Si substrate 2 is formed to have a (100) orientation. Then, the vertical gate electrode 1 is formed with an arrangement in which the orientations of the surfaces of the Si substrate 2 contacting the first surface 43 and the second surface 44 of the embedded electrode part 12 are (110) orientations in the first configuration example and (100) orientations in the second configuration example.

On the other hand, in the cases of the third and fourth configuration examples of the vertical gate electrode 1 mentioned above, the substrate surface of the Si substrate 2 is formed to have a (111) orientation. Then, the vertical gate electrode 1 is formed with an arrangement in which the orientation of the surface of the Si substrate 2 contacting the first surface 43 of the embedded electrode part 12 is a (112) orientation in the third configuration example and a (110) orientation in the fourth configuration example. At this time, the orientation of the surface of the Si substrate 2 contacting the second surface 44 of the embedded electrode part 12 is a (110) orientation in the third configuration example and a (112) orientation in the fourth configuration example.

In the method of manufacturing the vertical gate electrode 1 mentioned above, after the opening 61A corresponding to the embedded lower electrode 12A is formed in the Si substrate 2A, the silicon layer 2B is formed by epitaxial growth, and the openings 61B corresponding to the embedded upper electrode 12B are formed in the formed silicon layer 2B. By forming the openings 61 of the embedded electrode part 12 at two steps as the opening 61A and the openings 61B in such a manner, variations in the depth direction of the embedded electrode part 12 can be suppressed.

### 7. Layout Examples of Vertical Transistor

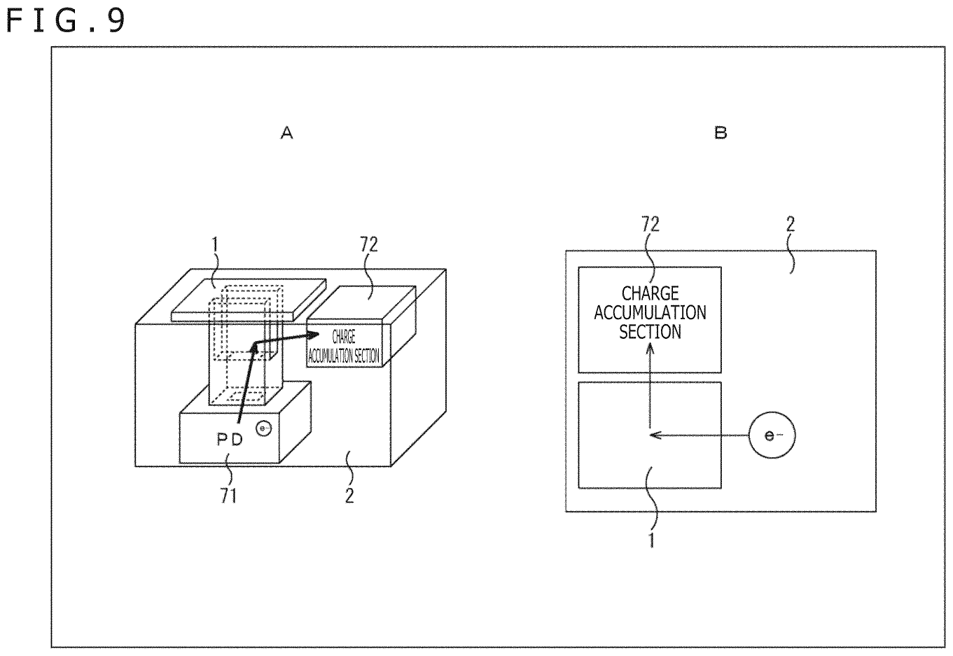

Layout examples of the vertical transistor using the vertical gate electrode 1 according to the first embodiment are explained with reference to FIG. 9 to FIG. 12. In each of FIG. 9 to FIG. 12, A on the left side depicts a perspective view, and B on the right side depicts a plan view.

FIG. 9 depicts a first layout example of the vertical transistor using the vertical gate electrode 1 according to the first embodiment.

In the first layout example in FIG. 9, a photodiode section 71 is formed on the lower side of the vertical gate electrode 1 (in the depth direction of the Si substrate 2). The photodiode section 71 generates and accumulates a charge according to the received light amount of incident light that is introduced from the backside of the Si substrate 2 which is a surface opposite to a surface where the vertical gate electrode 1 is formed. In addition, a charge accumulation section 72 which is the transfer destination of the charge generated by the photodiode section 71 is arranged at a position adjacent to the vertical gate electrode 1 in the plane direction. For example, the charge accumulation section 72 includes an n-type high concentration impurity region. In a case where a predetermined ON voltage is applied to the vertical gate electrode 1 and where the vertical transistor of the vertical gate electrode 1 is turned on, the charge accumulated in the photodiode section 71 is transferred to the charge accumulation section 72.

For example, in a case where the vertical transistor with the first layout is used for a pixel circuit of a CMOS image sensor, the vertical transistor using the vertical gate electrode 1 can be applied to a transfer transistor that reads out the charge of the photodiode section 71, and the charge accumulation section 72 can be used as an FD (Floating Diffusion).

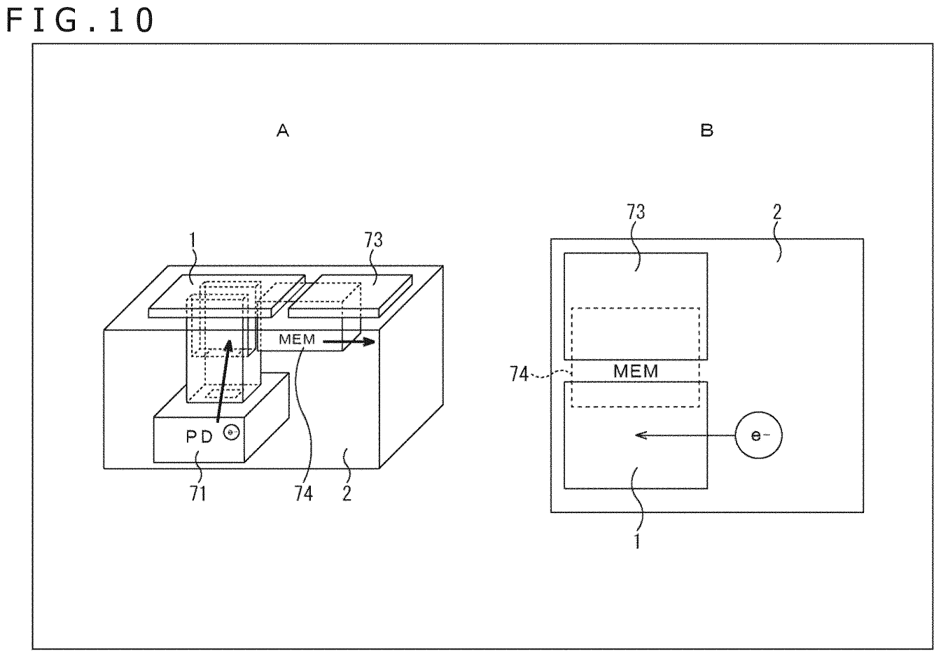

FIG. 10 depicts a second layout example of the vertical transistor using the vertical gate electrode 1.

In the second layout example in FIG. 10, the photodiode section 71 is arranged on the lower side of the vertical gate electrode 1 (in the depth direction of the Si substrate 2), and a gate electrode 73 of another transistor (hereinafter, referred to as an adjacent transistor) is arranged at a position adjacent to the vertical gate electrode 1 in the plane direction. The adjacent transistor includes a planar transistor having the gate electrode 73 formed only on the substrate surface. Further, a charge accumulation section 74 that accumulates a charge transferred from the photodiode section 71 is formed in the Si substrate 2 between the vertical gate electrode 1 and the gate electrode 73.

In a case where a predetermined ON voltage is applied to the vertical gate electrode 1 and where the vertical transistor of the vertical gate electrode 1 is turned on, the charge accumulated in the photodiode section 71 is transferred to and retained in the charge accumulation section 74. Thereafter, in a case where a predetermined ON voltage is applied to the gate electrode 73 and where the adjacent transistor is turned on, the charge retained in the charge accumulation section 74 is transferred to a charge drain section which is not depicted.

For example, in a case where the vertical transistor with the second layout is used for a pixel circuit of a CMOS image sensor, the vertical transistor can be applied to a global shutter-type pixel circuit. Specifically, the vertical transistor using the vertical gate electrode 1 can be applied to a transfer transistor that reads out the charge of the photodiode section 71, and the charge accumulation section 74 can be used as a memory section that temporarily accumulates the charge.

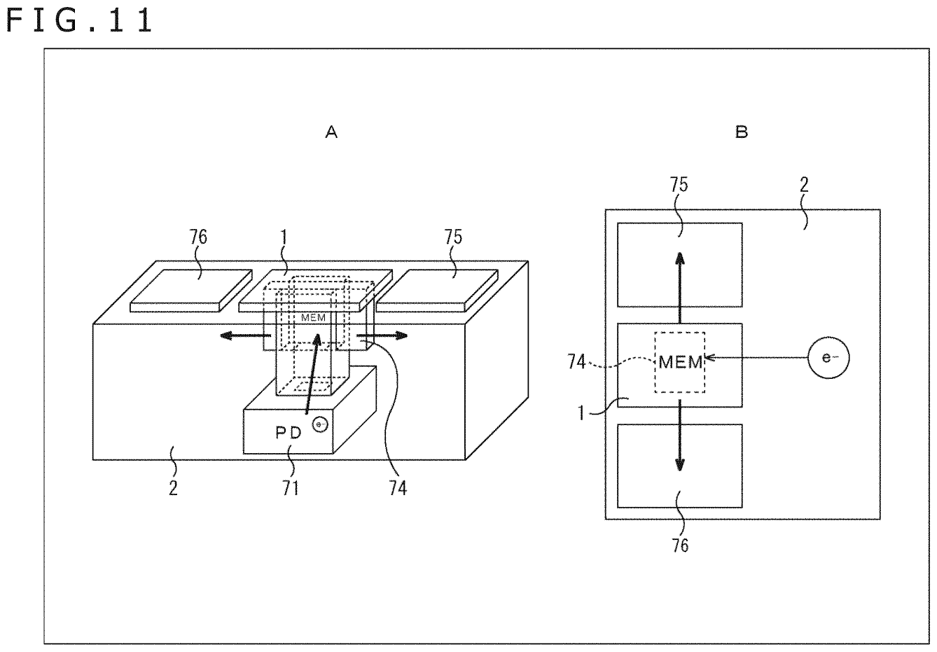

FIG. 11 depicts a third layout example of the vertical transistor using the vertical gate electrode 1.

In the third layout example in FIG. 11, the charge accumulation section 74 is formed on the lower side of the planar electrode part 11 of the vertical gate electrode 1 and between the two plate electrodes included in the embedded upper electrode 12B. Further, the photodiode section 71 is arranged on the lower side of the embedded lower electrode 12A.

In addition, a gate electrode 75 of a first adjacent transistor is arranged on one side adjacent to the vertical gate electrode 1 in the plane direction, and a gate electrode 76 of a second adjacent transistor is arranged on the other side which is opposite to the one side where the gate electrode 75 is arranged. The first adjacent transistor and the second adjacent transistor include planar transistors having the gate electrodes formed only on the substrate surface.

In a case where a predetermined ON voltage is applied to the vertical gate electrode 1 and the vertical transistor of the vertical gate electrode 1 is turned on, the charge accumulated in the photodiode section 71 is transferred to and retained in the charge accumulation section 74. Thereafter, in a case where a predetermined ON voltage is applied to the gate electrode 75 of the first adjacent transistor and where the first adjacent transistor is turned on, the charge retained in the charge accumulation section 74 is transferred to a charge drain section (not depicted) on the side of the first adjacent transistor. On the other hand, in a case where a predetermined ON voltage is applied to the gate electrode 76 of the second adjacent transistor and where the second adjacent transistor is turned on, the charge retained in the charge accumulation section 74 is transferred to a charge drain section (not depicted) of the second adjacent transistor.

For example, in a case where the vertical transistor with the third layout is used for a pixel circuit of a CMOS image sensor, the vertical transistor can be applied to a global shutter-type pixel circuit, and can be applied to a pixel structure in which a transfer path for transferring the charge of the photodiode section 71 is switched depending on whether it is a time of readout or a time of reset.

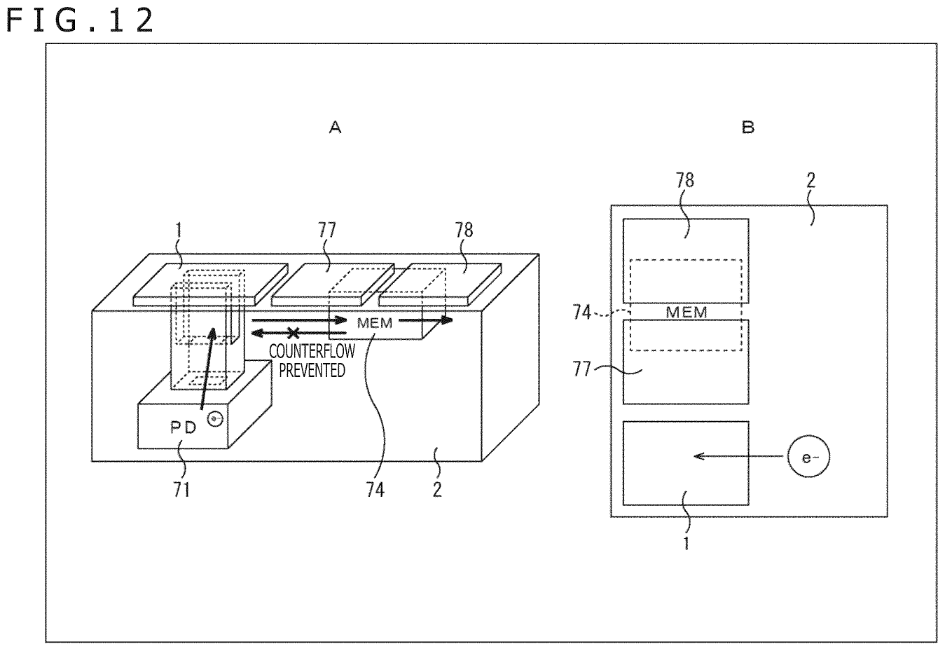

FIG. 12 depicts a fourth layout example of the vertical transistor using the vertical gate electrode 1.

In the fourth layout example in FIG. 12, the photodiode section 71 is arranged on the lower side of the vertical gate electrode 1, and a gate electrode 77 of the first adjacent transistor is arranged at a position adjacent to the vertical gate electrode 1 in the plane direction. In addition, a gate electrode 78 of the second adjacent transistor is arranged further next to the gate electrode 77 of the first adjacent transistor. Stated differently, the gate electrode 77 and the gate electrode 78 are arranged next to each other in a line on the same side of the vertical gate electrode 1. The first adjacent transistor and the second adjacent transistor include planar transistors having the gate electrodes formed only on the substrate surface. Further, the charge accumulation section 74 that accumulates a charge transferred from the photodiode section 71 is formed in the Si substrate 2 between the gate electrode 77 and the gate electrode 78.

In a case where a predetermined ON voltage is applied to the vertical gate electrode 1 and the gate electrode 77 and where both the vertical transistor and the first adjacent transistor are turned on, the charge accumulated in the photodiode section 71 is transferred to the charge accumulation section 74, and the charge is retained in the charge accumulation section 74 when the first adjacent transistor is turned off. Thereafter, in a case where a predetermined ON voltage is applied to the gate electrode 78 of the second adjacent transistor and where the second adjacent transistor is turned on, the charge retained in the charge accumulation section 74 is transferred to a charge drain section (not depicted) of the second adjacent transistor.

For example, in a case where the vertical transistor with the fourth layout is used for a pixel circuit of a CMOS image sensor, the vertical transistor can be applied to a global shutter-type pixel circuit, similarly to the second layout in FIG. 10. The vertical transistor using the vertical gate electrode 1 can be applied to a transfer transistor that reads out the charge of the photodiode section 71, and the charge accumulation section 74 can be used as a memory section that temporarily accumulates the charge. As compared with the second layout, the fourth layout can further prevent a counterflow of the charge accumulated in the charge accumulation section 74.

Also in the vertical transistors with the first to fourth layouts mentioned above, which have the above-mentioned vertical gate electrode 1, it is possible to facilitate the transfer of a charge from a photodiode section formed at a deep position in the substrate.

### 8. Modification Examples of Vertical Gate Electrode

In the example mentioned above, the vertical gate electrode 1 includes the planar electrode part 11 and the embedded electrode part 12, and the embedded electrode part 12 includes the embedded upper electrode 12B which includes the two plate electrodes facing each other and extending from the substrate surface of the Si substrate 2 to a predetermined depth, and the embedded lower electrode 12A which is a rectangular tube with a hollow inside.

However, the structures of the embedded upper electrode 12B and the embedded lower electrode 12A are not limited to those described above. For example, the embedded upper electrode 12B may not have two plate electrodes but have one plate electrode or three or four plate electrodes. In addition, the planar shape of the embedded lower electrode 12A need not be a rectangular tube, and may include four separate L-shaped corners of a rectangle, for example. That is, it is sufficient if the structure is arranged such that a degree of modulation of the embedded lower electrode 12A is increased over the degree of modulation of the embedded upper electrode 12B, and it is sufficient if the embedded lower electrode 12A is formed to have an electrode area size in a plan view which is greater than the electrode area size of the embedded upper electrode 12B. Accordingly, the degree of modulation of the embedded lower electrode 12A is increased, and it is possible to facilitate the transfer of a charge from a photodiode section formed at a deep position in the substrate.

### 9. Basic Structure of Vertical Gate Electrode According to Second Embodiment of Present Disclosure

Next, a vertical gate electrode according to a second embodiment of the present disclosure is explained. Note that portions in the second embodiment explained below that are common to the portions in the first embodiment mentioned above are given identical reference signs, and explanations of those portions are omitted as appropriate.

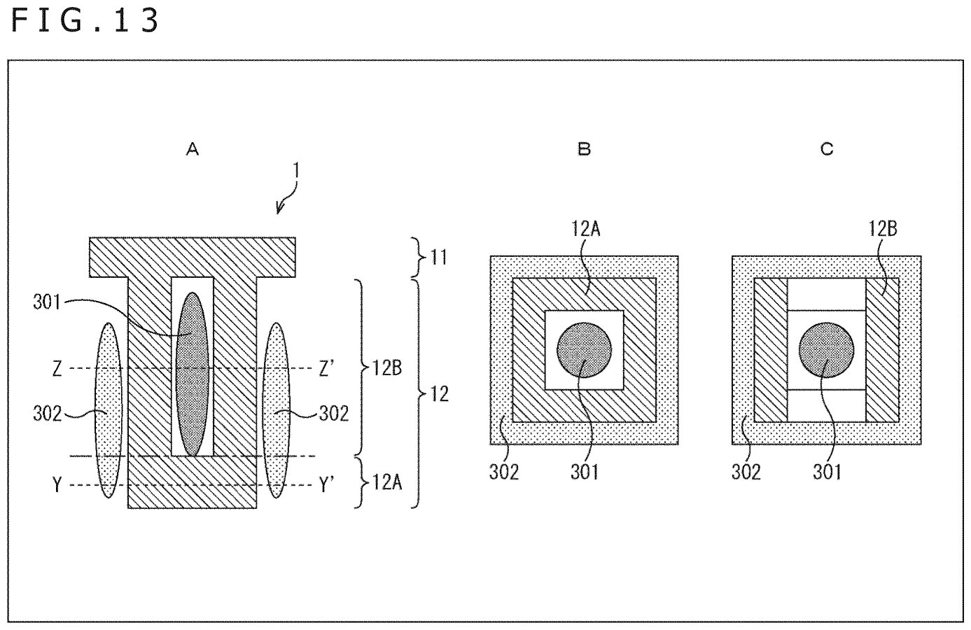

FIG. 13 depicts views of the basic structure of the vertical gate electrode according to the second embodiment of the present disclosure.

A of FIG. 13 is a cross-sectional view of the vertical gate electrode, B of FIG. 13 is a plan view of the vertical gate electrode taken along a line Y-Y′ in A of FIG. 13, and C of FIG. 13 is a plan view of the vertical gate electrode taken along a line Z-Z′ in A of FIG. 13. Although the perspective view of the vertical gate electrode depicted in A of FIG. 1 according to the first embodiment is omitted in FIG. 13, the cross-sectional view in A of FIG. 13 is a cross-sectional view taken along the line X-X′ in A of FIG. 1, similarly to that depicted in B of FIG. 1 according to the first embodiment.

The vertical gate electrode 1 according to the second embodiment has the planar electrode part 11 arranged at a position higher than the substrate surface, and the embedded electrode part 12 embedded in the substrate. The embedded electrode part 12 includes two separate electrodes, i.e., the embedded lower electrode 12A on the substrate deep-portion side relative to the dashed line and the embedded upper electrode 12B on the substrate-surface side relative to the dashed line. The embedded lower electrode 12A is formed as a rectangular tube with a hollow inside in a plan view, and the embedded upper electrode 12B has two plate electrodes facing each other.

Accordingly, the structures of the planar electrode part 11 and the embedded electrode part 12 of the vertical gate electrode 1 according to the second embodiment are the same as those according to the first embodiment mentioned above. On the other hand, the vertical gate electrode 1 according to the second embodiment is different from that according to the first embodiment mentioned above in that an impurity region of a predetermined conductivity type is further formed on a semiconductor layer (Si substrate 2) around the embedded electrode part 12. Specifically, in the second embodiment, as depicted in A to C of FIG. 13, an impurity region 301 of a first conductivity type is formed inside the embedded electrode part 12 in a plan view, and an impurity region 302 of a second conductivity type is also formed outside the embedded electrode part 12 in the plan view, the second conductivity type being opposite to the conductivity type of the inner impurity region 301. As depicted in B and C of FIG. 13, the impurity region 302 is formed to surround the outer periphery of the rectangular embedded electrode part 12 in a plan view. The impurity concentration of the impurity region 301 inside the embedded electrode part 12 is made higher than the impurity concentration of the impurity region 302 outside the embedded electrode part 12. In addition, the impurity concentration of the impurity region 301 inside the embedded electrode part 12 increases as the distance to the substrate surface decreases, i.e., as the substrate depth decreases.

### 10. First Configuration Example of Vertical Gate Electrode According to Second Embodiment

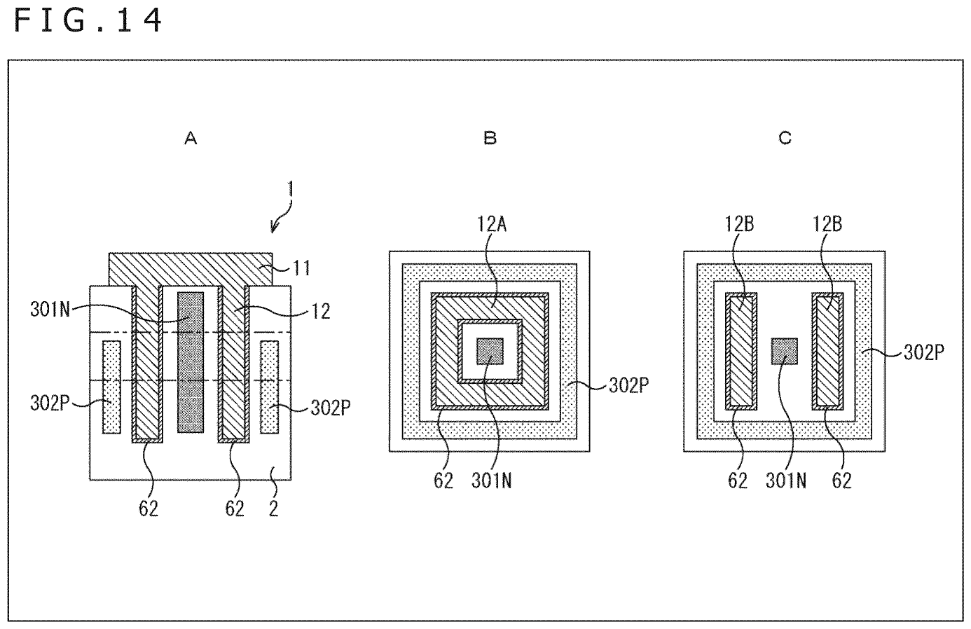

FIG. 14 depicts a more specific first configuration example of the vertical gate electrode 1 according to the second embodiment in FIG. 13.

A of FIG. 14 is a cross-sectional view of the vertical gate electrode 1 in the first configuration example, B of FIG. 14 is a plan view of the vertical gate electrode 1 in the first configuration example taken along the line Y-Y′ in FIG. 13, and C of FIG. 14 is a plan view of the vertical gate electrode 1 in the first configuration example taken along the line Z-Z′ in FIG. 13.

The vertical gate electrode 1 in the first configuration example represents a configuration example in a case where a signal charge is electrons.

In a case where a signal charge is electrons, the impurity region 301 inside the embedded electrode part 12 is an N-type impurity region 301N, and the impurity region 302 outside the embedded electrode part 12 is a P-type impurity region 302P.

The N-type impurity region 301N is formed at a depth which is substantially the same as the depth of the embedded electrode part 12, and may be formed deeper than the embedded electrode part 12 or may be formed shallower than the embedded electrode part 12. The impurity concentration of the impurity region 301N increases as the distance to the substrate surface decreases, i.e., as the substrate depth decreases.

The lower end of the P-type impurity region 302P is set to a depth which is not deeper than that of the embedded electrode part 12, and the upper end of the impurity region 302P is set to a position which is higher than (closer to the substrate surface than) the upper end of the tubular embedded lower electrode 12A represented by a dash-dotted line but lower (deeper) than the upper end of the impurity region 301N. For example, the upper end of the impurity region 302P is set to a position lower (deeper) than an intermediate position of the embedded upper electrode 12B in the depth direction which is represented by a double-dotted line. The pinning regions 62 including P-type impurity regions are formed in regions to predetermined depths (thicknesses) from the side walls and bottom surfaces of the embedded electrode part 12, similarly to the first embodiment.

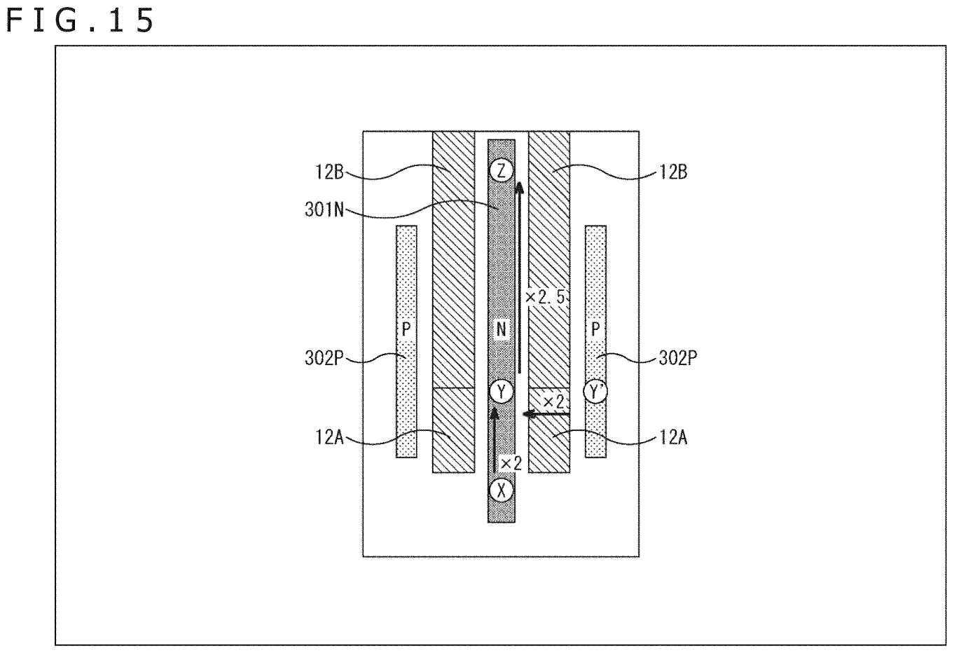

FIG. 15 is a view for explaining a suitable impurity concentration of each of the N-type impurity region 301N and the P-type impurity region 302P.

A position which is in a region inside the embedded electrode part 12 and is lower (deeper) than the bottom surface of the tubular embedded lower electrode 12A is defined as a position X, a position which is in the region inside the embedded electrode part 12 and is near the upper end of the tubular embedded lower electrode 12A, i.e., near the connection point between the embedded lower electrode 12A and the embedded upper electrode 12B, is defined as a position Y, a position which is in the region inside the embedded electrode part 12 and is near the substrate surface is defined as a position Z, and a position which is at the same depth as the position Y and is outside the embedded electrode part 12 is defined as a position Y′.

Using the impurity concentration at the position X near the bottom surface of the embedded lower electrode 12A as a reference concentration, the impurity concentration at the position Y is preferably made approximately twice as high as the impurity concentration at the position X, and the impurity concentration at the position Z is preferably made approximately five times as high as the impurity concentration at the position X (approximately 2.5 times as high as the impurity concentration at the position Y). In addition, the impurity concentration at the position Y′ is preferably made substantially the same as the impurity concentration at the position X. Stated differently, the impurity concentration at the position Y is preferably made approximately twice as high as the impurity concentration at the position Y′. For example, in a case where the impurity concentration at the position X is set to 1.5E16 [/cm³], the impurity concentration at the position Y′ is 1.5E16 [/cm³], the impurity concentration at the position Y is 3.0E16 [/cm³], and the impurity concentration at the position Z is 7.5E16 [/cm³].

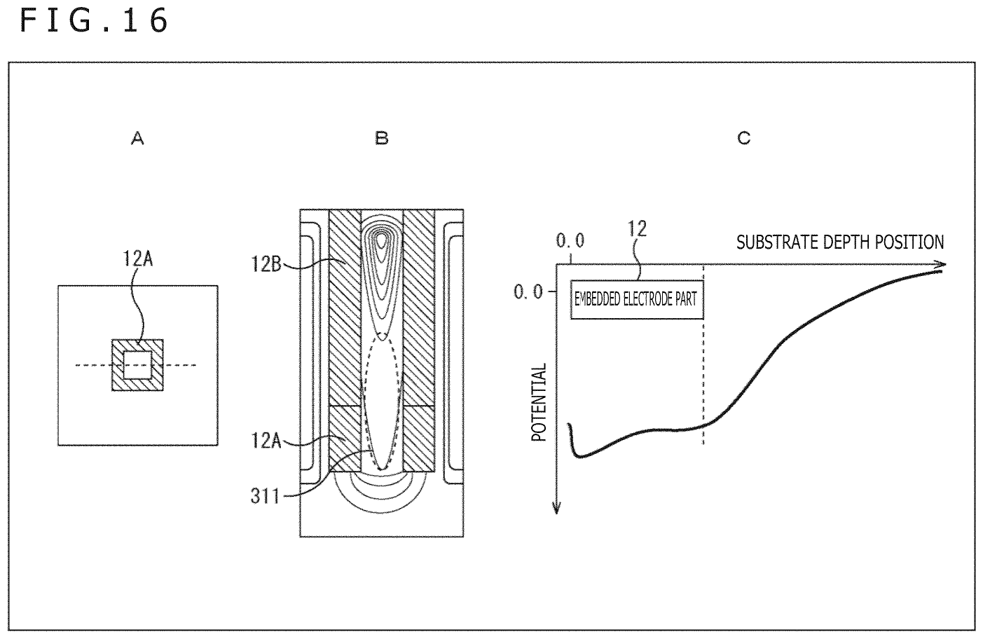

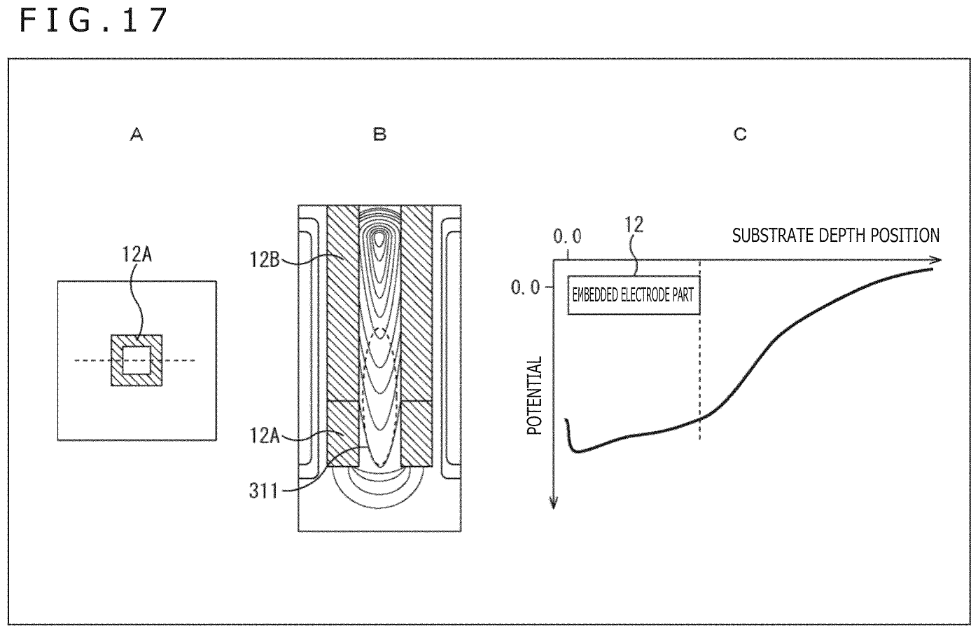

FIG. 16 and FIG. 17 are views depicting simulation results of electrical fields formed by the vertical gate electrode 1 according to the first embodiment and the second embodiment.

FIG. 16 depicts a result of simulation with the vertical gate electrode 1 according to the first embodiment, and FIG. 17 depicts a result of simulation with the vertical gate electrode 1 according to the second embodiment.

In each of FIG. 16 and FIG. 17, the cross-sectional view in B in the middle depicts equipotential lines (equipotential surfaces) around the embedded electrode part 12, and the plan view in A on the left side depicts, with a broken line, a cross-sectional line of the cross-sectional view in B in the middle. The graph in C on the right side depicts the potential at positions (substrate depth positions) in the substrate depth direction relative to the substrate surface which is a reference surface (0.0).

The potential graph in the first embodiment depicted in C of FIG. 16 is identical to the potential graph depicted in B of FIG. 3.

Attention is paid to electrical fields of the regions inside the embedded electrode parts 12 represented by oval broken lines in equipotential lines in B of FIG. 16 and B of FIG. 17. Equipotential lines 311 in B of FIG. 16 and B of FIG. 17 represent identical potential. According to comparison of electrical fields in the regions represented by the oval broken lines, as compared with the first embodiment in B of FIG. 16, there are three more equipotential lines in the second embodiment in B of FIG. 17. Intervals between the three equipotential lines are also almost constant intervals. This difference between the electrical fields can also be seen in comparison of the potential graphs in C of FIG. 16 and C of FIG. 17. While the potential near the bottom of the embedded electrode part 12 is almost constant (horizontal) in the potential graph according to the first embodiment in C of FIG. 16, the potential changes from an upper portion (substrate surface) of the embedded electrode part 12 to the bottom at a constant inclination in the potential graph according to the second embodiment in C of FIG. 17.

As mentioned above, in the vertical gate electrode 1 according to the second embodiment, with the impurity regions 301 and 302 (the impurity region 301N and the impurity region 302P), which are opposite conductivity types, formed inside and outside the embedded electrode part 12, the electrical field inside the embedded electrode part 12 can be given such a potential gradient that facilitates the transfer of a signal charge. Hence, it is possible to improve the transfer of a signal charge from a photodiode section formed at a deep position in the substrate.

### 11. Method of Manufacturing Vertical Gate Electrode According to Second Embodiment

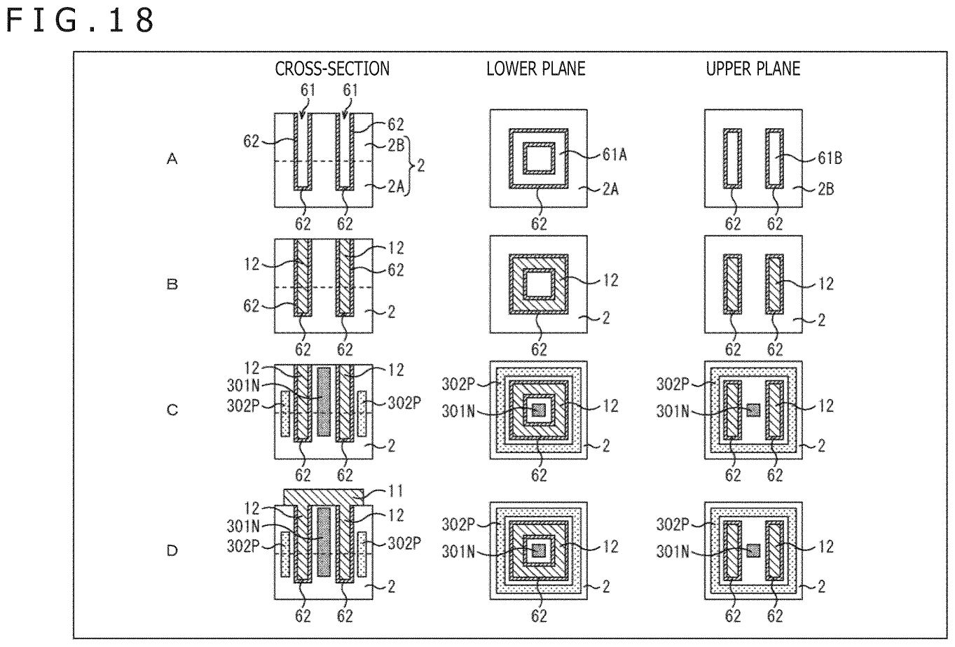

Next, a method of manufacturing the vertical gate electrode 1 according to the second embodiment is explained with reference to FIG. 18. FIG. 18 is for explaining a method of manufacturing the vertical gate electrode 1 in the first configuration example depicted in FIG. 14. Similarly to FIG. 8, in FIG. 18, cross-sectional views of the vertical gate electrode 1 at the time of formation are depicted on the left side, plan views equivalent to the portion of the embedded lower electrode 12A are depicted at the center, and plan views equivalent to the portion of the embedded upper electrode 12B are depicted on the right side.

The method of manufacturing the vertical gate electrode 1 according to the second embodiment is identical to the method of manufacturing the vertical gate electrode 1 according to the first embodiment explained with reference to FIG. 8 up to an intermediate step. Specifically, since it is the same as the method of manufacturing the vertical gate electrode 1 according to the first embodiment from the step in A of FIG. 8 to the step in G of FIG. 8, the state which is the same as the cross-sectional view and plan views in G of FIG. 8 is represented by the cross-sectional view and plan views in A of FIG. 18, and explanations of identical steps are omitted. As a result of the steps up to A of FIG. 18, the openings 61 have been formed in the Si substrate 2, and the pinning regions 62 have been formed in regions to predetermined depths (thicknesses) from the side walls and bottom surfaces of the openings 61 by implanting P-type ions such as boron on the side walls and bottom surfaces of the openings 61.

Gate insulating films (not depicted) are formed on the side walls and bottom surfaces of the openings 61 after the step in A of FIG. 18, and then, as depicted in B of FIG. 18, the embedded electrode part 12 is formed by embedding an electrically conductive material such as metal or polysilicon in the openings 61.

Next, as depicted in C of FIG. 18, the N-type impurity region 301N is formed by implanting N-type ions such as phosphorus in the Si substrate 2 (semiconductor layer) inside the embedded electrode part 12. In addition, the P-type impurity region 302P is formed by implanting P-type ions such as boron to a predetermined depth in the Si substrate 2 at the outer periphery portion of the embedded electrode part 12. Whichever of the impurity region 301N and the impurity region 302P may be formed earlier.

Next, after a gate insulating film (not depicted) is formed on the substrate top surface of the Si substrate 2 other than the embedded electrode part 12, as depicted in D of FIG. 18, the planar electrode part 11 is formed by patterning of an electrically conductive material which is the same as the embedded electrode part 12, on the substrate top surface of the Si substrate 2, and the vertical gate electrode 1 of FIG. 13 is completed.

### 12. Second Configuration Example of Vertical Gate Electrode According to Second

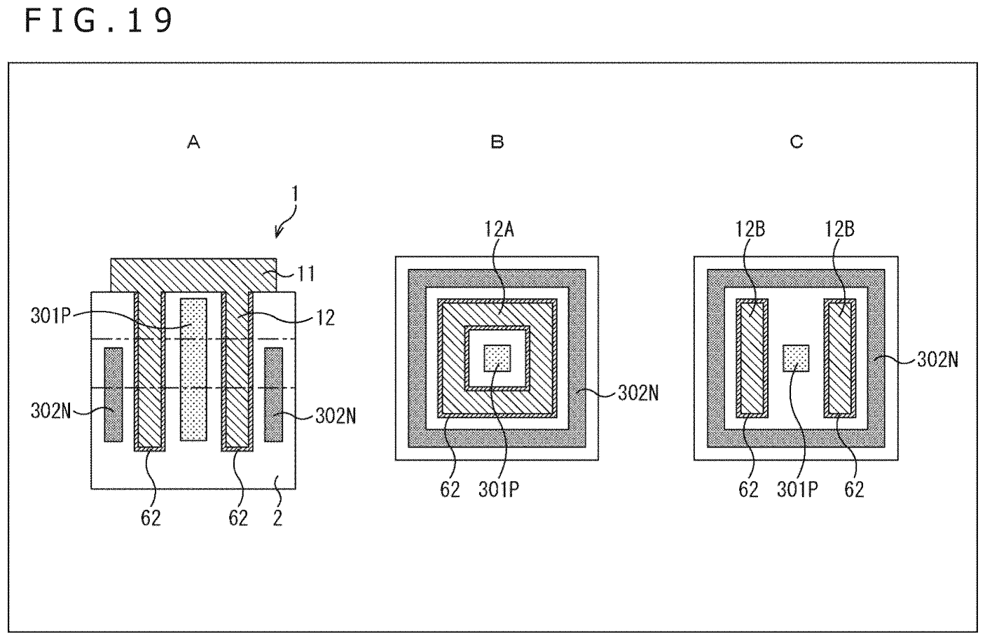

FIG. 19 depicts a more specific second configuration example of the vertical gate electrode 1 according to the second embodiment in FIG. 13.

A of FIG. 19 is a cross-sectional view of the vertical gate electrode 1 in the second configuration example, B of FIG. 19 is a plan view of the vertical gate electrode 1 in the second configuration example taken along the line Y-Y′ in FIG. 13, and C of FIG. 19 is a plan view of the vertical gate electrode 1 in the second configuration example taken along the line Z-Z′ in FIG. 13.

The vertical gate electrode 1 in the second configuration example represents a configuration example in a case where a signal charge is holes.

In a case where a signal charge is holes, the impurity region 301 inside the embedded electrode part 12 is a P-type impurity region 301P, and the impurity region 302 outside the embedded electrode part 12 is an N-type impurity region 302N.

The P-type impurity region 301P is formed at a depth which is substantially the same as the depth of the embedded electrode part 12, and may be formed deeper than the embedded electrode part 12 or may be formed shallower than the embedded electrode part 12. The impurity concentration of the impurity region 301P increases as the distance to the substrate surface decreases, i.e., as the substrate depth decreases.

The lower end of the N-type impurity region 302N is set to a depth which is not deeper than the embedded electrode part 12, and the upper end of the impurity region 302N is set to a position which is higher than (closer to the substrate surface than) the upper end of the tubular embedded lower electrode 12A represented by a dash-dotted line but lower (deeper) than the upper end of the impurity region 301P. For example, the upper end of the impurity region 302N is set to a position lower (deeper) than an intermediate position of the embedded upper electrode 12B in the depth direction which is represented by a double-dotted line. The respective suitable impurity concentrations of the P-type impurity region 301P and the N-type impurity region 302N are similar to those in the first configuration example explained with reference to FIG. 15. Whereas, similarly to the first embodiment, the pinning regions 62 are formed in regions to predetermined depths (thicknesses) from the side walls and bottom surfaces of the embedded electrode part 12, the pinning regions 62 are formed by using N-type impurity regions in a case where a signal charge is holes.

### 13. Third Configuration Example of Vertical Gate Electrode According to Second

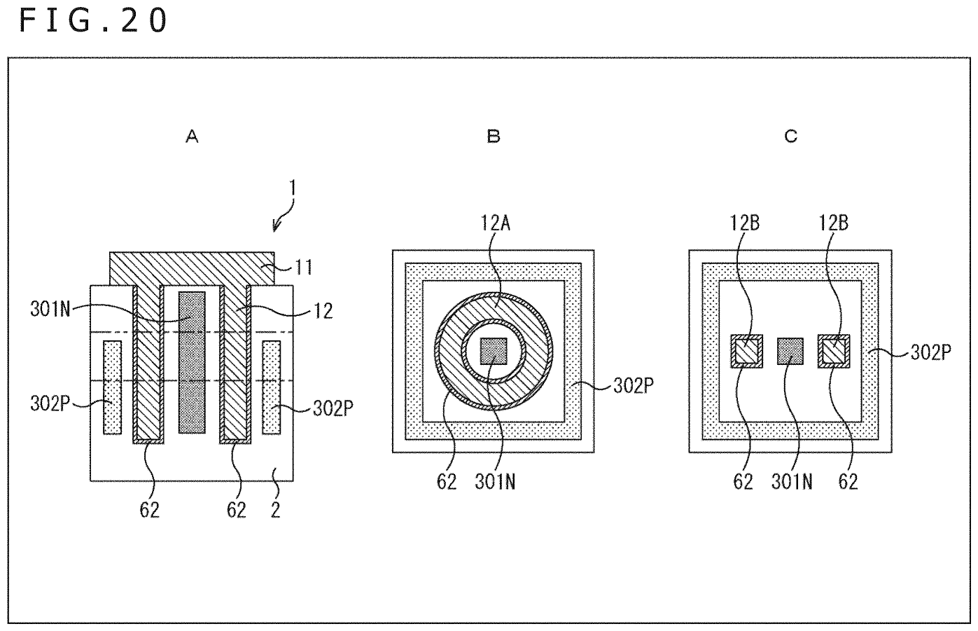

FIG. 20 depicts a more specific third configuration example of the vertical gate electrode 1 according to the second embodiment in FIG. 13.

A of FIG. 20 is a cross-sectional view of the vertical gate electrode 1 in the third configuration example, B of FIG. 20 is a plan view of the vertical gate electrode 1 in the third configuration example taken along the line Y-Y′ in FIG. 13, and C of FIG. 20 is a plan view of the vertical gate electrode 1 in the third configuration example taken along the line Z-Z′ in FIG. 13.

As compared with the vertical gate electrode 1 in the first configuration example depicted in FIG. 14, the vertical gate electrode 1 in the third configuration example has a different planar shape of the tubular embedded lower electrode 12A. Specifically, whereas the planar shape of the embedded lower electrode 12A is a rectangle in the first configuration example in FIG. 14, it is formed in a circle in the third configuration example in FIG. 20. The planar shape of the embedded upper electrode 12B connecting the tubular embedded lower electrode 12A and the planar electrode part 11 is changed to a rectangle with a smaller aspect ratio than that in the first configuration example in FIG. 14 such that it matches the circular planar shape of the embedded lower electrode 12A. In other respects, the third configuration example is similar to the first configuration example depicted in FIG. 14.

Whereas the planar shape of the tubular embedded lower electrode 12A is a circle in the example in FIG. 20, it may be an oval.

### 14. Fourth Configuration Example of Vertical Gate Electrode According to Second Embodiment

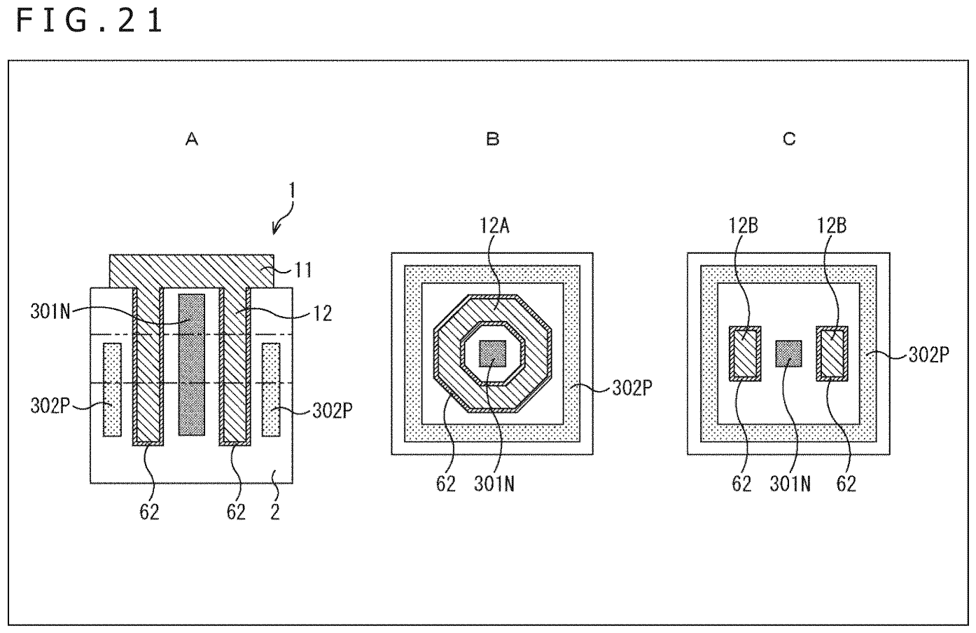

FIG. 21 depicts a more specific fourth configuration example of the vertical gate electrode 1 according to the second embodiment in FIG. 13.

A of FIG. 21 is a cross-sectional view of the vertical gate electrode 1 in the fourth configuration example, B of FIG. 21 is a plan view of the vertical gate electrode 1 in the fourth configuration example taken along the line Y-Y′ in FIG. 13, and C of FIG. 21 is a plan view of the vertical gate electrode 1 in the fourth configuration example taken along the line Z-Z′ in FIG. 13.

As compared with the vertical gate electrode 1 in the first configuration example depicted in FIG. 14, the vertical gate electrode 1 in the fourth configuration example has a different planar shape of the tubular embedded lower electrode 12A. Specifically, whereas the planar shape of the embedded lower electrode 12A is a rectangle in the first configuration example in FIG. 14, it is formed in an octagon in the fourth configuration example in FIG. 21. The planar shape of the embedded upper electrode 12B connecting the tubular embedded lower electrode 12A and the planar electrode part 11 is changed to a rectangle with a smaller aspect ratio than that in the first configuration example in FIG. 14 such that it matches the octagonal planar shape of the embedded lower electrode 12A. In other respects, the fourth configuration example is similar to the first configuration example depicted in FIG. 14.

Whereas the planar shape of the tubular embedded lower electrode 12A is an octagon in the example in FIG. 21, it may be a polygon other than an octagon.

### 15. Summary of Vertical Gate Electrode According to Second Embodiment

The vertical gate electrode 1 according to the second embodiment mentioned above includes the planar electrode part 11 and the embedded electrode part 12, and includes the impurity region (first impurity region) 301 of a first conductivity type formed inside the embedded electrode part 12 in a plan view, and the impurity region (second impurity region) 302 of a second conductivity type formed outside the embedded electrode part 12 in the plan view, the second conductivity type being opposite to the first conductivity type. The impurity concentration of the impurity region 301 inside the embedded electrode part 12 is made higher than the impurity concentration of the impurity region 302 outside the embedded electrode part 12. In addition, the impurity concentration of the impurity region 301 inside the embedded electrode part 12 increases as the distance to the substrate surface decreases, i.e., as the substrate depth decreases.

According to the second embodiment, the electrical field inside the embedded electrode part 12 can be given such a potential gradient that further facilitates the transfer of a signal charge, thereby further improving the transfer of a signal charge from a photodiode section formed at a deep position in the substrate, than the case in the first embodiment.

The vertical gate electrode 1 according to the second embodiment has a structure similar to the structure of the vertical gate electrode 1 according to the first embodiment, but additionally has the impurity region 301 of the first conductivity type and the impurity region 302 of the second conductivity type. Accordingly, the configuration of the Si substrate 2 and the configurations of the orientations of the substrate surface 42 of the Si substrate 2 and the first surface 43 and the second surface 44 of the embedded electrode part 12 explained in the first embodiment can similarly be applied to the vertical gate electrode 1 according to the second embodiment. In addition, also in the vertical gate electrode 1 according to the second embodiment, each layout of the vertical transistor explained with reference to FIG. 9 to FIG. 12 can be applied.

### 16. Example of Application to Solid-State Imaging Element

The technology according to the present disclosure can be applied to semiconductor devices in general having a semiconductor integrated circuit using a vertical transistor. For example, examples of semiconductor devices to which the technology according to the present disclosure can be applied include a solid-state imaging element including at least, in each pixel, a photodiode section as a photo-electric converting section, and a transistor that transfers a charge generated by the photodiode section.

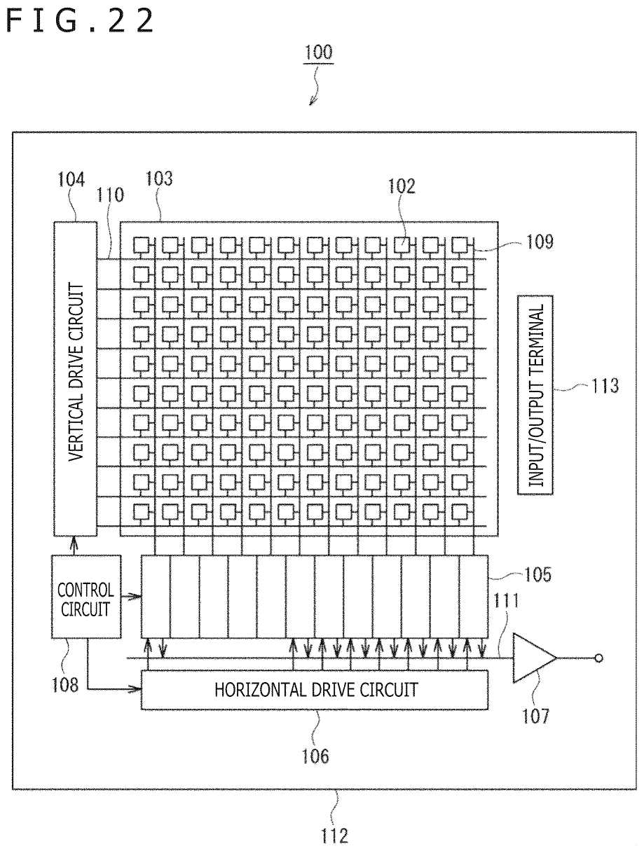

FIG. 22 depicts the schematic configuration of a solid-state imaging element to which the technology according to the present disclosure is applied.

A solid-state imaging element 100 depicted in FIG. 22 has, on a semiconductor substrate 112 using, for example, silicon (Si) as a semiconductor, a pixel array section 103 having two-dimensionally arrayed pixels 102, and a peripheral circuit section around the pixel array section 103. The peripheral circuit section includes a vertical drive circuit 104, column signal processing circuits 105, a horizontal drive circuit 106, an output circuit 107, a control circuit 108, and the like.

For example, each pixel 102 in the pixel array section 103 has a photodiode section as a photo-electric converting section, a floating diffusion (floating diffusion region), and a plurality of pixel transistors. For example, the plurality of pixel transistors includes four MOS transistor, i.e., a transfer transistor, a selection transistor, a reset transistor, and an amplification transistor. As the transfer transistor arranged in each pixel 102, the vertical transistor having the vertical gate electrode 1 mentioned above can be adopted.

The pixels 102 can also have a shared pixel structure. The shared pixel structure includes a plurality of photodiode sections, a plurality of transfer transistors, one shared floating diffusion (floating diffusion region), and each one of other shared pixel transistors. That is, in the shared pixel structure, the photodiodes and transfer transistors included in a plurality of unit pixels share each one of the other pixel transistors. Also in this case, as the transfer transistors arranged in the unit pixels, the vertical transistors each having the vertical gate electrode 1 mentioned above can be adopted.

The control circuit 108 receives an input clock and data which is a command for an operation mode or the like, and outputs data such as internal information regarding the solid-state imaging element 100. That is, the control circuit 108 generates a reference clock signal or a control signal for operation of the vertical drive circuit 104, the column signal processing circuits 105, the horizontal drive circuit 106, and the like, on the basis of a vertical synchronization signal, a horizontal synchronization signal, and a master clock. Then, the control circuit 108 outputs the generated clock signal or control signal to the vertical drive circuit 104, the column signal processing circuits 105, the horizontal drive circuit 106, and the like.

For example, the vertical drive circuit 104 includes a shift register, selects a predetermined pixel driving wire 110, supplies pulses for driving pixels 102 to the selected pixel driving wire 110, and drives the pixels 102 in units of rows. That is, the vertical drive circuit 104 selects and scans each pixel 102 in the pixel array section 103 sequentially in units of rows in the vertical direction, and supplies, to a column signal processing circuit 105 through a vertical signal line 109, a pixel signal based on a signal charge generated according to a received light amount at the photo-electric converting section of each pixel 102.

Each column signal processing circuit 105 is arranged for one column of pixels 102, and performs signal processing of noise removal and the like for each pixel column on signals output from pixels 102 in one row. For example, each column signal processing circuit 105 performs signal processing such as CDS (Correlated Double Sampling) for removing fixed pattern noise unique to pixels or AD conversion.

For example, the horizontal drive circuit 106 includes a shift register, selects each of the column signal processing circuits 105 sequentially by sequentially outputting horizontal scanning pulses, and causes each of the column signal processing circuits 105 to output pixel signals to a horizontal signal line 111.

The output circuit 107 performs predetermined signal processing on pixel signals sequentially supplied through the horizontal signal line 111 from each of the column signal processing circuits 105, and outputs the pixel signals. For example, the output circuit 107 performs only buffering in some cases, or performs various types of digital signal processing such as black level adjustment or column-wise variation correction, and the like, in some cases. An input/output terminal 113 exchanges signals with the outside.

The solid-state imaging element 100 configured as described above is an image sensor called a column-AD-scheme CMOS image sensor in which a column signal processing circuit 105 that performs a CDS process and an AD conversion process is arranged for each pixel column. In addition, it is a back-illuminated CMOS image sensor in which incident light is introduced from the backside which is opposite to a surface where pixel transistors of the semiconductor substrate 112 are formed.

The vertical transistor having the vertical gate electrode 1 mentioned above can be adopted as a transfer transistor of the pixel 102 of such a solid-state imaging element 100. Hence, modulation at the distal end portion of the vertical gate electrode 1 can be increased locally, and it is possible to facilitate the transfer of a charge at a deeper portion in the semiconductor substrate 112.

### 17. Example of Application to Electronic Equipment

The technology according to the present disclosure can be applied to electronic equipment in general that uses a solid-state imaging element for an image capturing section (photo-electric converting section). Examples of the electronic equipment include an imaging apparatus such as a digital still camera or a video camera, a mobile terminal apparatus having an imaging function, and a copying machine that uses a solid-state imaging element for an image reading section. The solid-state imaging element may have a form formed as one chip, or may have a modular form having an imaging function in which an imaging section and a signal processing section or an optical system are packaged collectively.

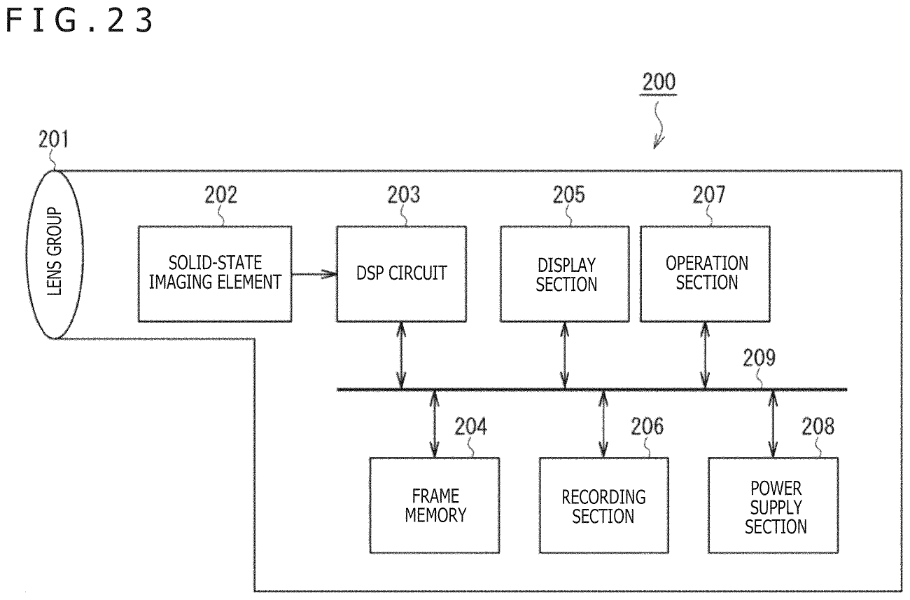

FIG. 23 is a block diagram depicting a configuration example of an imaging apparatus as the electronic equipment to which the technology according to the present disclosure is applied.

An imaging apparatus 200 in FIG. 23 includes an optics section 201 including a lens group or the like, a solid-state imaging element (imaging device) 202 for which the configuration of the solid-state imaging element 100 in FIG. 22 is adopted, and a DSP (Digital Signal Processor) circuit 203 which is a camera signal processing circuit. In addition, the imaging apparatus 200 also includes a frame memory 204, a display section 205, a recording section 206, an operation section 207, and a power supply section 208. The DSP circuit 203, the frame memory 204, the display section 205, the recording section 206, the operation section 207, and the power supply section 208 are interconnected via a bus line 209.

The optics section 201 takes in incident light (image light) from a subject and forms an image of the light on an imaging surface of the solid-state imaging element 202. The solid-state imaging element 202 converts light amounts of the incident light whose image is formed on the imaging surface by the optics section 201, into electric signals in units of pixels, and outputs the electric signals as pixel signals. As this solid-state imaging element 202, it is possible to use the solid-state imaging element 100 in FIG. 22, that is, the solid-state imaging element having the pixels 102 for which the vertical transistor having the vertical gate electrode 1 is adopted as the transfer transistor.

For example, the display section 205 includes a panel-type display device such as a liquid crystal panel or an organic EL (Electro Luminescence) panel, and displays a video or still images captured with the solid-state imaging element 202. The recording section 206 records the video or still images captured with the solid-state imaging element 202, on a recording medium such as a hard disk or a semiconductor memory.

According to an operation made by a user, the operation section 207 issues operation commands regarding various functions of the imaging apparatus 200. The power supply section 208 serves as various types of power supply as operation power supplies of supply targets which are the DSP circuit 203, the frame memory 204, the display section 205, the recording section 206, and the operation section 207, as appropriate.

As mentioned above, it is possible to facilitate the transfer of a charge from a photodiode section formed at a deep position in the substrate, by using, as the solid-state imaging element 202, the solid-state imaging element 100 including, in each pixel, the transfer transistor having the vertical gate electrode 1 mentioned above. Accordingly, in the imaging apparatus 200 such as a video camera, a digital still camera, or a camera module for a mobile phone or other mobile equipment, it is possible to attempt to increase the image quality of captured images.

In addition, the technology according to the present disclosure can be applied not only to solid-state imaging elements that detect the distribution of incident light amounts of visible light and form an image of the visible light, but also to solid-state imaging elements that form an image on the basis of the distribution of amounts of incidence of infrared rays, X-rays, particles, or the like, and solid-state imaging elements (physical quantity distribution detecting devices) in general such as a fingerprint detection sensor that detects the distribution of another physical quantity such as pressure or electrostatic capacitance and forms an image, in a broad sense.

### 18. Example of Application to Endoscopic Surgery System

The technology according to the present disclosure can be applied to various products. For example, the technology according to the present disclosure may be applied to an endoscopic surgery system.

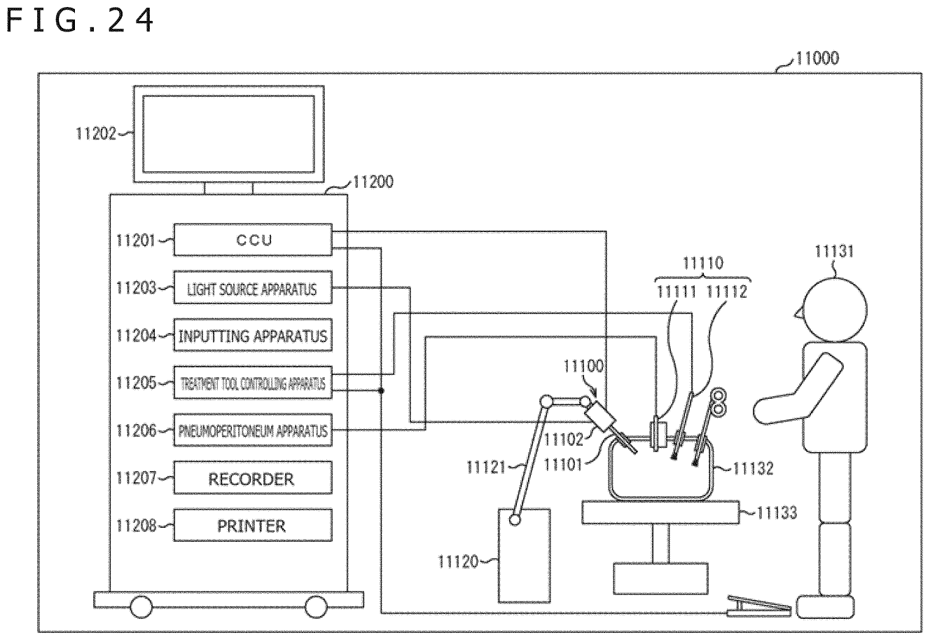

FIG. 24 is a view depicting an example of a schematic configuration of an endoscopic surgery system to which the technology according to an embodiment of the present disclosure (present technology) can be applied.

In FIG. 24, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

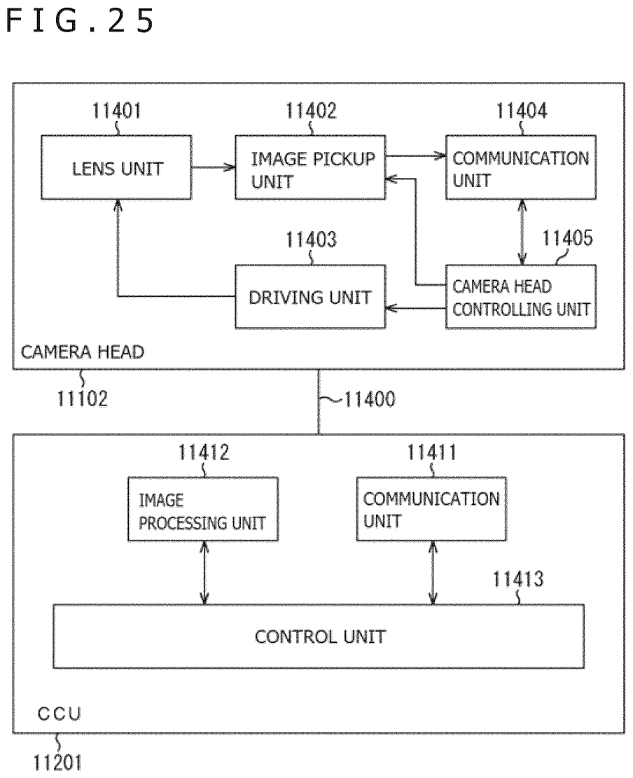

FIG. 25 is a block diagram depicting an example of a functional configuration of the camera head 11102 and the CCU 11201 depicted in FIG. 24.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of an endoscopic surgery system to which the technology according to the present disclosure can be applied has been explained thus far. The technology according to the present disclosure can be applied to the image pickup unit 11402 of the camera head 11102 in the configuration explained above. Specifically, a solid-state imaging element having pixels that adopt, as transfer transistors, vertical transistors each having the vertical gate electrode 1 can be applied as the image pickup unit 11402. By applying the technology according to the present disclosure to the image pickup unit 11402, clearer surgical-region images can be obtained while the size of the camera head 11102 is reduced.

Note that, whereas an endoscopic surgery system has been explained as an example here, the technology according to the present disclosure may be applied to others such as a microscopic surgery system, for example.

### 19. Example of Application to Mobile Body

The technology according to the present disclosure can be applied to various products. For example, the technology according to the present disclosure may be realized as an apparatus to be mounted on any type of mobile body such as an automobile, an electric automobile, a hybrid electric automobile, a motorcycle, a bicycle, a personal mobility, an airplane, a drone, a ship, or a robot.

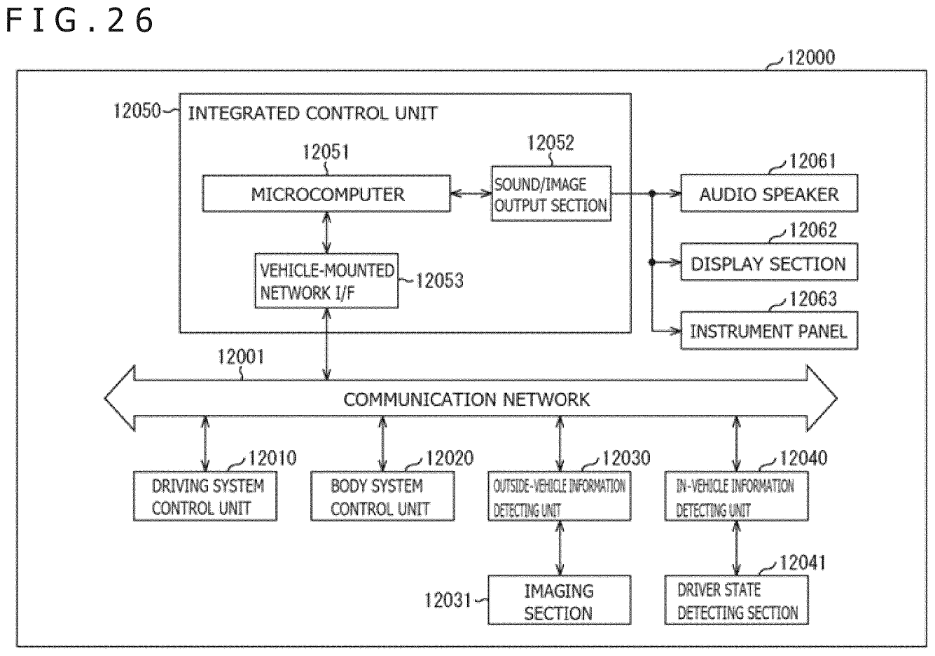

FIG. 26 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 26, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 26, an audio speaker 12061, a display section 12062, and an instrument panel 12063 are illustrated as the output device. The display section 12062 may, for example, include at least one of an on-board display and a head-up display.

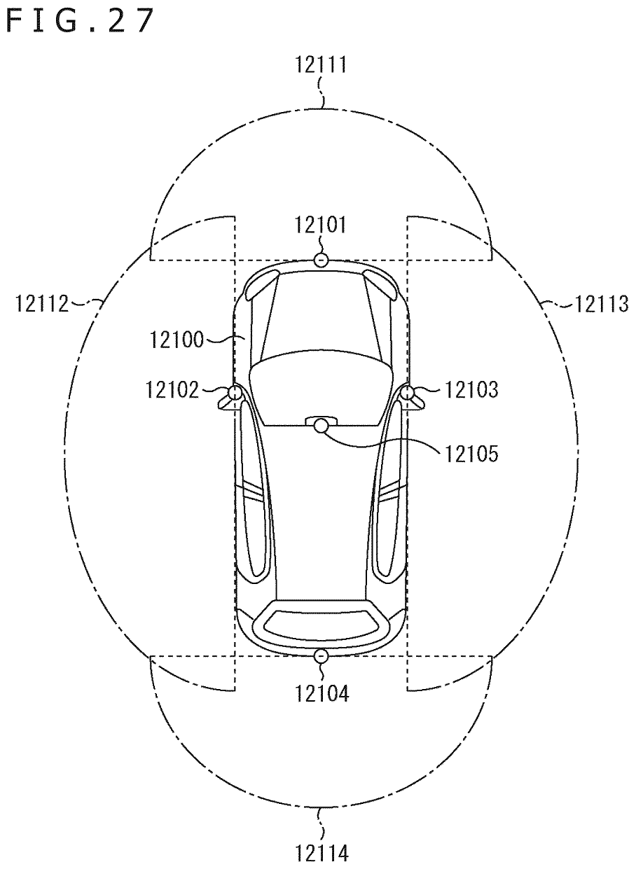

FIG. 27 is a diagram depicting an example of the installation position of the imaging section 12031.

In FIG. 27, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 27 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of a vehicle control system to which the technology according to the present disclosure can be applied has been explained thus far. The technology according to the present disclosure can be applied to the imaging section 12031 in the configuration explained above. Specifically, a solid-state imaging element having pixels that adopt, as transfer transistors, vertical transistors each having the vertical gate electrode 1 can be applied as the imaging section 12031. By applying the technology according to the present disclosure to the imaging section 12031, captured images which are easier to see can be obtained, and distance information can be acquired while size reduction is achieved. In addition, by using the obtained captured images or distance information, it becomes possible to mitigate fatigue felt by a driver, and enhance the degree of safety of a driver or a vehicle.

Embodiments of the present disclosure are not limited to the embodiments mentioned above, and can be changed in various manners within the scope not departing from the gist of the technology according to the present disclosure.

Whereas the semiconductor device in which electrons are treated as a signal charge is explained in the examples mentioned above, the technology according to the present disclosure can also be applied to semiconductor devices in which holes are treated as a signal charge. In this case, the conductivity type of each semiconductor region in a semiconductor substrate is the opposite conductivity type.

Advantages described in the present specification are presented merely for illustrative purposes but not for limiting the advantages. There may be advantages other than those described in the present specification.

Note that the technology according to the present disclosure can also take the following configurations.

(1)

A semiconductor device including:
a photo-electric converting section that generates a charge according to a received light amount; and
a transfer transistor that transfers the charge of the photo-electric converting section to a predetermined charge accumulation section, in which
the transfer transistor has a vertical gate electrode including an embedded electrode part embedded in a semiconductor substrate, and
the embedded electrode part includes an embedded upper electrode and an embedded lower electrode that is arranged on a substrate deep-portion side relative to the embedded upper electrode and that is formed to have an electrode area size, in a plan view, greater than an electrode area size of the embedded upper electrode.
   (2)

The semiconductor device according to (1) above, in which
the embedded lower electrode is formed as a rectangular tube.
   (3)

The semiconductor device according to (1) or (2) above, in which
the embedded upper electrode is formed as two plates facing each other.
   (4)

The semiconductor device according to any one of (1) to (3) above, in which
the semiconductor substrate is a Si (100) substrate, and
an orientation of a surface of the semiconductor substrate contacting a side surface of the embedded electrode part includes a (110) orientation.
   (5)

The semiconductor device according to any one of (1) to (3) above, in which
the semiconductor substrate is a Si (100) substrate, and
an orientation of a surface of the semiconductor substrate contacting a side surface of the embedded electrode part includes a (100) orientation.
   (6)

The semiconductor device according to any one of (1) to (3) above, in which
the semiconductor substrate is a Si (111) substrate, and
an orientation of a surface of the semiconductor substrate contacting a longer-side side surface of the embedded electrode part in a plan view includes a (112) orientation.
   (7)

The semiconductor device according to any one of (1) to (3) above, in which
the semiconductor substrate is a Si (111) substrate, and
an orientation of a surface of the semiconductor substrate contacting a longer-side side surface of the embedded electrode part in a plan view includes a (110) orientation.
   (8)

The semiconductor device according to any one of (1) to (7) above, in which
the predetermined charge accumulation section includes a high concentration impurity region.
   (9)

The semiconductor device according to any one of (1) to (7) above, further including:
another transistor arranged at a position adjacent to the transfer transistor in a plane direction, in which
the predetermined charge accumulation section is formed between the transfer transistor and the other transistor.
   (10)

The semiconductor device according to any one of (1) to (7) above, further including:
a first adjacent transistor arranged at a position adjacent to the transfer transistor in a first direction; and
a second adjacent transistor arranged at a position adjacent to the transfer transistor in a second direction opposite to the first direction, in which
a charge of the predetermined charge accumulation section is transferred by the first adjacent transistor or transferred by the second adjacent transistor.
   (11)

The semiconductor device according to any one of (1) to (7) above, further including:
a first adjacent transistor arranged at a position adjacent to the transfer transistor in a first direction; and
a second adjacent transistor arranged at a position adjacent to the first adjacent transistor in the first direction, in which
the predetermined charge accumulation section is formed between the first adjacent transistor and the second adjacent transistor.
   (12)

The semiconductor device according to any one of (1) to (11) above, in which
the semiconductor device includes a solid-state imaging element, and
each pixel of the solid-state imaging element includes the photo-electric converting section and the transfer transistor.
   (13)

The semiconductor device according to any one of (1) to (11) above, in which
the transfer transistor includes a first impurity region of a first conductivity type that is formed inside the embedded electrode part in a plan view, and a second impurity region of a second conductivity type that is formed outside the embedded electrode part in the plan view, the second conductivity type being opposite to the first conductivity type.
   (14)

The semiconductor device according to (13) above, in which
one of the first conductivity type and the second conductivity type is a P-type, and the other one is an N-type.
   (15)

The semiconductor device according to any one of (1) to (14) above, in which
a planar shape of the embedded lower electrode is a circle or an oval.
   (16)

The semiconductor device according to any one of (1) to (14) above, in which
a planar shape of the embedded lower electrode is a polygon.
   (17)

A method of manufacturing a semiconductor device, including:
forming an embedded electrode part embedded in a semiconductor substrate, as a vertical gate electrode of a transfer transistor that transfers a charge generated according to a received light amount by a photo-electric converting section to a predetermined charge accumulation section, in which
the embedded electrode part includes an embedded upper electrode and an embedded lower electrode that is arranged on a substrate deep-portion side relative to the embedded upper electrode and that is formed to have an electrode area size, in a plan view, greater than an electrode area size of the embedded upper electrode.
   (18)

The method of manufacturing a semiconductor device according to (17) above, further including:
forming an opening for the embedded lower electrode in the semiconductor substrate;
forming an opening for the embedded upper electrode in a semiconductor layer further formed on the semiconductor substrate by epitaxial growth; and
forming the embedded electrode part by embedding an electrically conductive material in the openings for the embedded upper electrode and the embedded lower electrode.
   (19)

The method of manufacturing a semiconductor device according to (17) above, further including:
forming an opening for the embedded lower electrode in the semiconductor substrate;
forming an opening for the embedded upper electrode in a semiconductor layer further formed on the semiconductor substrate by epitaxial growth;
forming the embedded electrode part by embedding an electrically conductive material in the openings for the embedded upper electrode and the embedded lower electrode; and
forming a first impurity region of a first conductivity type inside the embedded electrode part in a plan view, and forming a second impurity region of a second conductivity outside the embedded electrode part in the plan view, the second conductivity type being opposite to the first conductivity type.
   (20)

Electronic equipment including:
a semiconductor device including
   a photo-electric converting section that generates a charge according to a received light amount, and
   a transfer transistor that transfers the charge of the photo-electric converting section to a predetermined charge accumulation section,
   the transfer transistor having a vertical gate electrode including an embedded electrode part embedded in a semiconductor substrate, and
   the embedded electrode part including an embedded upper electrode and an embedded lower electrode that is arranged on a substrate deep-portion side relative to the embedded upper electrode and that is formed to have an electrode area size, in a plan view, greater than an electrode area size of the embedded upper electrode.

### REFERENCE SIGNS LIST

1: Vertical gate electrode
2: Si substrate
2A: Si substrate
2B: Silicon layer
11: Planar electrode part
12: Embedded electrode part
12A: Embedded lower electrode
12B: Embedded upper electrode
21: Vertical gate electrode
22: Planar electrode part
23: Embedded electrode part
42: Substrate surface
43: First surface
44: Second surface
61, 61A, 61B: Opening
62: Pinning region
63: Silicon oxide
65: Electrically conductive material
71: Photodiode section
72: Charge accumulation section
73: Gate electrode
74: Charge accumulation section
75 to 78: Gate electrode
100: Solid-state imaging element
102: Pixel
200: Imaging apparatus
202: Solid-state imaging element
301, 301N, 301P: Impurity region
302, 302N, 302P: Impurity region

What is claimed is:

1. A semiconductor device, comprising:
a photo-electric converting section that generates a charge according to a received light amount; and
a transfer transistor that transfers the charge of the photo-electric converting section to a predetermined charge accumulation section, wherein
the transfer transistor has a vertical gate electrode including an embedded electrode part embedded in a semiconductor substrate, and
the embedded electrode part includes an embedded upper electrode and an embedded lower electrode that is arranged on a substrate deep-portion side relative to the embedded upper electrode and that is formed to have an electrode area size, in a plan view, greater than an electrode area size of the embedded upper electrode.

2. The semiconductor device according to claim 1, wherein
the embedded lower electrode is formed as a rectangular tube.

3. The semiconductor device according to claim 1, wherein
the embedded upper electrode is formed as two plates facing each other.

4. The semiconductor device according to claim 1, wherein
the semiconductor substrate is a Si (100) substrate, and
an orientation of a surface of the semiconductor substrate contacting a side surface of the embedded electrode part includes a (110) orientation.

5. The semiconductor device according to claim 1, wherein
the semiconductor substrate is a Si (100) substrate, and
an orientation of a surface of the semiconductor substrate contacting a side surface of the embedded electrode part includes a (100) orientation.

6. The semiconductor device according to claim 1, wherein
the semiconductor substrate is a Si (111) substrate, and
an orientation of a surface of the semiconductor substrate contacting a longer-side side surface of the embedded electrode part in a plan view includes a (112) orientation.

7. The semiconductor device according to claim 1, wherein
the semiconductor substrate is a Si (111) substrate, and
an orientation of a surface of the semiconductor substrate contacting a longer-side side surface of the embedded electrode part in a plan view includes a (110) orientation.

8. The semiconductor device according to claim 1, wherein
the predetermined charge accumulation section includes a high concentration impurity region.

9. The semiconductor device according to claim 1, further comprising:
another transistor arranged at a position adjacent to the transfer transistor in a plane direction, wherein
the predetermined charge accumulation section is formed between the transfer transistor and the other transistor.

10. The semiconductor device according to claim 1, further comprising:
a first adjacent transistor arranged at a position adjacent to the transfer transistor in a first direction; and
a second adjacent transistor arranged at a position adjacent to the transfer transistor in a second direction opposite to the first direction, wherein
a charge of the predetermined charge accumulation section is transferred by the first adjacent transistor or transferred by the second adjacent transistor.

11. The semiconductor device according to claim 1, further comprising:
a first adjacent transistor arranged at a position adjacent to the transfer transistor in a first direction; and
a second adjacent transistor arranged at a position adjacent to the first adjacent transistor in the first direction, wherein
the predetermined charge accumulation section is formed between the first adjacent transistor and the second adjacent transistor.

12. The semiconductor device according to claim 1, wherein
the semiconductor device includes a solid-state imaging element, and
each pixel of the solid-state imaging element includes the photo-electric converting section and the transfer transistor.

13. The semiconductor device according to claim 1, wherein
the transfer transistor includes a first impurity region of a first conductivity type that is formed inside the embedded electrode part in a plan view, and a second impurity region of a second conductivity type that is formed outside the embedded electrode part in the plan view, the second conductivity type being opposite to the first conductivity type.

14. The semiconductor device according to claim 13, wherein
one of the first conductivity type and the second conductivity type is a P-type, and the other one is an N-type.

15. The semiconductor device according to claim 1, wherein
a planar shape of the embedded lower electrode is a circle or an oval.

16. The semiconductor device according to claim 1, wherein
a planar shape of the embedded lower electrode is a polygon.

17. A method of manufacturing a semiconductor device, comprising:
forming an embedded electrode part embedded in a semiconductor substrate, as a vertical gate electrode of a transfer transistor that transfers a charge generated according to a received light amount by a photo-electric converting section to a predetermined charge accumulation section, wherein
the embedded electrode part includes an embedded upper electrode and an embedded lower electrode that is arranged on a substrate deep-portion side relative to the embedded upper electrode and that is formed to have an electrode area size, in a plan view, greater than an electrode area size of the embedded upper electrode.

18. The method of manufacturing a semiconductor device according to claim 17, further comprising:
forming an opening for the embedded lower electrode in the semiconductor substrate;
forming an opening for the embedded upper electrode in a semiconductor layer further formed on the semiconductor substrate by epitaxial growth; and
forming the embedded electrode part by embedding an electrically conductive material in the openings for the embedded upper electrode and the embedded lower electrode.

19. The method of manufacturing a semiconductor device according to claim 17, further comprising:
forming an opening for the embedded lower electrode in the semiconductor substrate;
forming an opening for the embedded upper electrode in a semiconductor layer further formed on the semiconductor substrate by epitaxial growth;
forming the embedded electrode part by embedding an electrically conductive material in the openings for the embedded upper electrode and the embedded lower electrode; and
forming a first impurity region of a first conductivity type inside the embedded electrode part in a plan view, and forming a second impurity region of a second conductivity type outside the embedded electrode part in the plan view, the second conductivity type being opposite to the first conductivity type.

20. Electronic equipment, comprising:
a semiconductor device including
a photo-electric converting section that generates a charge according to a received light amount, and
a transfer transistor that transfers the charge of the photo-electric converting section to a predetermined charge accumulation section,
the transfer transistor having a vertical gate electrode including an embedded electrode part embedded in a semiconductor substrate, and
the embedded electrode part including an embedded upper electrode and an embedded lower electrode that is arranged on a substrate deep-portion side relative to the embedded upper electrode and that is formed to have an electrode area size, in a plan view, greater than an electrode area size of the embedded upper electrode.
